(19) United States
(12) Patent Application Publication
(10) Pub. No.: US 2015/0000728 A1
(43) Pub. Date: Jan. 1, 2015

(54) TITANIUM OXIDE LAMINATED FILM, TITANIUM OXIDE FILM, MANUFACTURING METHOD FOR SAME, PRECURSOR LIQUID FOR TITANIUM OXIDE, AND DYE-SENSITIZED AGENT TYPE PHOTOELECTRIC CONVERSION ELEMENT

(71) Applicant: Tokyo Institute of Technology, Tokyo (JP)

(72) Inventors: Masato Maitani, Tokyo (JP); Keita Tanaka, Tokyo (JP); Yuji Wada, Tokyo (JP)

(21) Appl. No.: 14/369,154

(22) PCT Filed: Dec. 19, 2012
(86) PCT No.: PCT/JP2012/008128

§ 371 Date: Jun. 26, 2014

(30) Foreign Application Priority Data
Dec. 26, 2011 (JP) 2011-282584

(51) Int. Cl. H01G 9/20; H01L 29/24; H01L 29/04; H01L 21/02

(52) U.S. Cl. CPC H01G 9/2031; H01G 9/2059; H01L 21/02565; H01L 21/02628; H01L 29/24; H01L 29/045
USPC 136/252; 257/43; 438/104; 252/519.3

(57) ABSTRACT

Provided is a titanium oxide laminated film that includes the titanium oxide film consisting of anatase-type plate-like crystals in which (001) faces with a high chemical activity are grown more than normal and the (001) faces are grown in a vertical or inclined direction with respect to a deposition surface of a base material, and is capable of having a specific surface area greater than that of the titanium oxide film alone. A titanium oxide laminated film (1) is formed by sequentially laminating, on a base material (11), a first titanium oxide film (12) consisting of a plurality of anatase-type plate-like crystals in which (001) faces are grown in a vertical or inclined direction with respect to a deposition surface (11a) of the base material (11), and a second titanium oxide film (13) having a specific surface area greater than that of the first titanium oxide film (12) and consisting of a plurality of titanium oxide fine particles.

### TECHNICAL FIELD

The present invention relates to a titanium oxide laminated film, a titanium oxide film, a manufacturing method for the same, a titanium oxide liquid precursor preferably used for manufacturing the titanium oxide film, and a dye-sensitized agent type photoelectric conversion element using the titanium oxide film as a semiconductor film that supports a dye-sensitized agent.

### BACKGROUND ART

In general, a negative electrode substrate of a dye-sensitized agent type photoelectric conversion element has a structure in which a translucent conductive film consisting of FTO (Fluorine-doped Tin Oxide), ITO (Indium Tin Oxide) or the like and a semiconductor film consisting of a titanium oxide that supports a dye-sensitized agent are sequentially formed as a negative electrode on a translucent substrate formed of a glass substrate or the like.

In the dye-sensitized type photoelectric conversion element, the titanium oxide film plays a role to support the dye-sensitized agent for absorbing light and collect excited electrons thereof. Therefore, the titanium oxide film for supporting the dye-sensitized agent is required to have a specific surface area necessary for supporting the dye-sensitized agent and favorable conductivity.

In related arts, a porous film consisting of nano-order titanium oxide fine particles (the porous film hereinafter referred to as a “titanium oxide fine particle film”) is widely used for the titanium oxide film that supports the dye-sensitized agent.

There are several crystal types in the titanium oxide. Because of its favorable electronic property and favorable optical property, the anatase type is considered to be preferable to the rutile type.

The titanium oxide fine particle film used for a known dye-sensitized type photoelectric conversion element has a large specific surface area and is excellent in supporting a dye-sensitized agent. However, the titanium oxide fine particle film has a polycrystalline structure and poor conductivity due to an interface resistance between particles, thereby leading to a poor electron-injection efficiency and electron transfer property.

It is preferable that the titanium oxide film for supporting the dye-sensitized agent consists of single crystals with no interface resistance and the crystals are oriented with gaps therebetween for supporting the dye-sensitized agent.

In related arts, there have been attempts to control the crystal orientation of the titanium oxide film in vapor-phase film deposition. However, the vapor-phase process that requires a vacuum atmosphere is costly. In related arts, there is a known method for growing a titanium oxide film consisting of anatase-type crystals directly on a base material having a translucent conductive film such as a tin oxide film on its surface by the liquid-phase process such as the hydrothermal synthesis method and the electrolytic oxidation deposition method.

There are several crystal faces on an anatase-type titanium oxide crystal. Generally in the anatase-type titanium oxide crystal, due to its high chemical activity, the (001) face is unstable and difficult to grow, while other crystal faces have a low chemical activity and are thus stable, they are easy to grow.

In deposition of a titanium oxide film by the known liquid-phase process, the (101) face, which is the most stable face, is preferentially grown. The (101) face is a surface inclined with respect to the (001) face or the (100) face. Therefore, the titanium oxide film in which the (101) face is preferentially grown has low film uniformity and tends to have a structure where many crystal interfaces and crystal faults exist. The titanium oxide film in which the inactive (101) face is preferentially grown and many crystal interfaces and crystal faults exit is difficult to achieve a favorable electron-injection efficiency and electron transfer property in applications such as a dye-sensitized type photoelectric conversion element.

In recent years, Non-Patent Literature 1 has reported film deposition of an anatase-type titanium oxide film in which the (001) face is grown in a vertical direction or an inclined direction with respect to a deposition surface of a base material by the hydrothermal synthesis method.

The method disclosed in Non-Patent Literature 1 shall be described below.

An FTO substrate in which an FTO (Fluorine-doped Tin Oxide) film is formed on a glass substrate is prepared as a deposition base material.

36.5 to 38 mass % hydrochloric acid solution and deionized water are mixed to make a total amount of 60 ml, and the solution is stirred for five minutes.

0.5 g of (NH₄)₂TiF₆ and 1 ml of Ti(OBu)₄ (titanium tetrabutoxide) are added to the obtained solution, the solution is stirred for five minutes, and a liquid precursor is produced.

The above-mentioned liquid precursor is poured in a heat-resistant hermetically sealed container, and the deposition base material (the FTO substrate) is immersed in the liquid precursor.

This is reacted, for example, for twelve hours at 150° C. and air-cooled to a room temperature.

The base material which has been subjected to the hydrothermal synthesis is retrieved and ultrasonically cleaned with pure water.

### CITATION LIST

### Non Patent Literature

[Non-Patent Literature 1] Shuanglong Feng et. al., J. Ceram. Soc., 2011, 94[2], 310-315.
[Non-Patent Literature 2] Michele Lazzeri et. al., Phys. Rev. B, 2001, 63, 155409.
[Non-Patent Literature 3] Masato M. Maitani et. al., J. Phys. Chem. Lett. 2011, 2, 2655-2659.

### SUMMARY OF INVENTION

### Technical Problem

The method disclosed in Non-Patent Literature 1 is capable of depositing the anatase-type titanium oxide film in which the (001) faces with a high chemical activity are grown more than normal directly on a base material. However, the obtained titanium oxide film consists of plate-like crystals (e.g. FIG. 1 in Non-Patent Literature 1), and it is difficult to increase the specific surface area in comparison to a titanium oxide fine particle film of related arts. Therefore, in the dye-sensitized agent type photoelectric conversion element, when the titanium oxide film is used as a semiconductor film for supporting the dye-sensitized agent, it is difficult to increase the amount of the dye-sensitized agent to be supported.

In the anatase-type titanium oxide film in which the (001) faces with a high activity are grown more than normal, a ratio of the (001) faces to a total area of all crystal faces (the ratio hereinafter also referred to as a (001) face ratio) is preferably high.

Further, it is known that in the dye-sensitized type photoelectric conversion element using the titanium oxide film, the greater the actual surface/substrate projected area, the more dyes can be supported per substrate projected area, thereby increasing an absorption efficiency of incident light and improving the efficiency. Therefore, the actual surface area/substrate projected area of the titanium oxide film are preferably large.

Non-Patent Literature 1 does not disclose the (001) surface ratio and the actual surface area/substrate projected area and does not investigate the method to improve them.

Generally, in the dye-sensitized photoelectric conversion element of related arts, photoelectric conversion in a visible region (a wavelength region of 400 to 700 nm) is considered to be easy, while photoelectric conversion in an infrared region (a wavelength region of 700 to 900 nm) is considered to be difficult even by using a dye-sensitized agent having absorption in this wavelength region.

When infrared light can be photoelectrically converted together with visible light, it is possible to improve the photoelectric conversion efficiency more than when only the visible light is photoelectrically converted.

However, as a dye-sensitized agent that absorbs infrared light having a wavelength longer than that of the visible light have a narrow HOMO-LUMO gap, and a potential gap between LUMO of the dye-sensitized agent—titanium oxide conduction band will become narrow, it is considered to be difficult to perform photoelectric conversion due to deterioration in the electron-injection efficiency into a titanium oxide (see FIG. 4 of the specification of the present invention).

The present invention is made in light of the above-mentioned circumstances, and an object of the present invention is to provide a titanium oxide laminated film that includes a titanium oxide film consisting of anatase-type plate-like crystals in which (001) faces having a high chemical activity are grown more than normal and the (001) faces are grown in a vertical direction or an inclined direction with respect to a deposition surface of a base material and is capable of having a specific surface area greater than that of the titanium oxide alone.

Another object of the present invention is to provide a titanium oxide laminated film that includes a titanium oxide film consisting of anatase-type plate-like crystals in which (001) faces having a high chemical activity are grown more than normal and the (001) faces are grown in a vertical direction or an inclined direction with respect to a deposition surface of a base material, is capable of supporting a dye-sensitized agent, has a high chemical activity, a favorable electron-injection efficiency and electron transfer property, is capable of realizing photoelectric conversion, when used in a dye-sensitized type photoelectric conversion element, and can be manufactured at a low cost, and a photoelectric conversion agent type photoelectric conversion element including the titanium oxide laminated film.

Another object of the present invention is to provide a titanium oxide film consisting of anatase-type plate-like crystals in which (001) faces having a high chemical activity are grown more than usual, and the (001) faces are grown in a vertical direction or an inclined direction with respect to a deposition surface of a base material, and has an improved (001) face ratio and actual surface area/substrate projected area, a titanium oxide liquid precursor capable of manufacturing the titanium oxide film, and a manufacturing method of the titanium oxide film using the titanium oxide liquid precursor.

Another object of the present invention is to provide a dye-sensitized agent type photoelectric conversion element capable of realizing photoelectric conversion in an infrared region (a wavelength of 700 to 900 nm).

In the specification of the present invention, the phrase “(001) faces are grown more than usual” in an anatase-type titanium oxide, is defined in such a way that a ratio of areas of the (001) faces to a total area of all crystal faces of anatase-type crystals is greater than about 5% (e.g., as disclosed in Non-Patent Literature 2), which has normally been reported, and to be more specific, a ratio of the areas of the (001) faces to the total area of all crystal faces is 10% or greater.

### Solution to Problem

A titanium oxide laminated film according to the present invention includes:

a first titanium oxide film that consists of a plurality of anatase-type plate-like crystals, (001) faces of the anatase-type plate-like crystals are grown in a vertical direction or an inclined direction with respect to a deposition surface of a base material; and

a second titanium oxide film that has a specific area greater than a specific surface area of the first titanium oxide film and consists of a plurality of titanium oxide fine particles,

in which the first titanium oxide film and the second titanium oxide film are sequentially laminated on the base material.

It is preferable that, in the first titanium oxide film, an inclined angle of the (001) faces with respect to the deposition surface is 10° or greater

It is preferable that, in the first titanium oxide film, a ratio (a (001) face ratio) to a total area of all crystal faces of anatase-type crystals is 30% or greater.

It is preferable that, in the first titanium oxide film, an actual surface area/substrate projected area is 20 or greater.

In the specification of the present invention, the inclined angle of the (001) faces and the (001) face ratio of the anatase-type plate-like crystals are calculated by performing an SEM (Scanning Electron Microscope) observation, selecting 100 or more crystals at random, and calculating the inclined angle of the (001) faces and the (001) face ratio for each crystal.

A measurement method of the actual surface area/substrate projected area shall be described in the section [Example].

A titanium oxide film according to the present invention is

a titanium oxide film formed on a base material and consisting of a plurality of anatase-type plate-like crystals having (001) faces grown in a vertical direction or an inclined direction with respect to a deposition surface of the base material, in which

an inclined angle of the (001) faces with respect to the deposition surface is 10° or greater,

a ratio of areas of the (001) faces to a total area of all crystal faces of the anatase-type crystals is 10% or greater, and

an actual surface area/substrate projected area is 20 or greater.

A first titanium oxide liquid precursor according to the present invention is a titanium oxide liquid precursor that is used for depositing a titanium oxide film consisting of a plurality of anatase-type plate-like crystals having (001) faces grown in a vertical direction or an inclined direction with respect to a deposition surface of a base material, the first titanium oxide liquid precursor includes:

a titanium oxide precursor; and

a non-acidic additive agent consisting of a salt of [BF₄]⁻ and/or a salt of [PF₆]⁻.

A second titanium oxide liquid precursor is a titanium oxide liquid precursor that is used for depositing a titanium oxide film consisting of a plurality of anatase-type plate-like crystals having (001) faces grown in a vertical direction or an inclined direction with respect to a deposition surface of a base material, the second titanium oxide liquid precursor including:

a titanium oxide precursor; and

a non-acidic additive agent consisting of an alcohol and/or an amine.

A method of manufacturing a titanium oxide film consisting of a plurality of anatase-type plate-like crystals in which (001) faces are grown in a vertical direction or an inclined direction with respect to a deposition surface of a substrate, the method including:

depositing the titanium oxide film by a liquid-phase process using the above-mentioned first or second titanium oxide liquid precursor according to the present invention.

A first dye-sensitized agent type photoelectric conversion element according to the present invention includes:

a base material; and

a semiconductor film that supports a dye-sensitized agent,

in which the semiconductor film contains the above-mentioned titanium oxide laminated film according to the present invention.

A second dye-sensitized agent type photoelectric conversion element according to the present invention includes:

a base material; and

a semiconductor film that supports a dye-sensitized agent,

in which the semiconductor film contains the above-mentioned titanium oxide film consisting of anatase-type plate-like crystals according to the present invention.

In the first and second dye-sensitized agent type photoelectric conversion elements according to the present invention, a dye-sensitized agent that indicates absorption in a wavelength region of 700 to 900 nm is used as the dye-sensitized agent. In this case, a dye-sensitized agent type photoelectric conversion element can indicate a photoelectric conversion response in the wavelength region of 700 to 900 nm.

A third dye-sensitized agent type photoelectric conversion element according to the present invention includes:

a base material; and

a semiconductor film that supports a dye-sensitized agent, in which

the semiconductor film includes a titanium oxide film consisting of a plurality of anatase-type plate-like crystals, the anatase-type plate-like crystals having (001) faces grown in a vertical direction or an inclined direction with respect to a deposition surface of the substrate,

a dye-sensitized agent that indicates absorption in a wavelength region of 700 to 900 nm is used as the dye-sensitized agent, and

the dye-sensitized agent type photoelectric conversion element indicates a photoelectric conversion response in the wavelength region of 700 to 900 nm.

### Advantageous Effects of Invention

According to the present invention, it is possible to provide a titanium oxide laminated film that includes a titanium oxide film consisting of anatase-type plate-like crystals in which (001) faces having a high chemical activity are grown more than normal and the (001) faces are grown in a vertical direction or an inclined direction with respect to a deposition surface of a base material and is capable of having a specific surface area greater than that of the titanium oxide alone.

According to the present invention,

it is possible to provide the titanium oxide laminated film that includes the titanium oxide film consisting of anatase-type plate-like crystals in which the (001) faces having a high chemical activity are grown more than normal and the (001) faces are grown in the vertical direction or the inclined direction with respect to the deposition surface of the base material, is capable of supporting the dye-sensitized agent, has a high chemical activity, has a favorable electron-injection efficiency and a favorable electron transfer property, is capable of realizing a photoelectric conversion, when used in a dye-sensitized type photoelectric conversion element, and can be manufactured at a low cost, and a photoelectric conversion agent type photoelectric conversion element including the titanium oxide laminated film.

According to the present invention, it is possible to provide a titanium oxide film consisting of anatase-type plate-like crystals in which (001) faces having a high chemical activity are grown more than usual, and the (001) faces are grown in a vertical direction or an inclined direction with respect to a deposition surface of a base material, and have an improved (001) face ratio and actual surface area/substrate projected area, a titanium oxide liquid precursor capable of manufacturing the titanium oxide film, and a manufacturing method of the titanium oxide film using the titanium oxide liquid precursor.

According to the present invention, it is possible to provide a dye-sensitized agent type photoelectric conversion element that is capable of realizing photoelectric conversion in an infrared region (a wavelength region of 700 to 900 nm).

### BRIEF DESCRIPTION OF DRAWINGS

FIG. 1 is an image perspective diagram of a titanium oxide film consisting of anatase-type plate-like crystals;

FIG. 2 is an image perspective diagram of a titanium oxide laminated film according to the present invention;

FIG. 3 is a schematic cross-sectional diagram of a dye-sensitized type photoelectric conversion element according to an embodiment of the present invention;

FIG. 4 schematically shows an energy diagram of the dye-sensitized type photoelectric conversion element of FIG. 3;

FIG. 5 shows an XRD pattern of an FTO substrate and a TiO₂/FTO substrate obtained in Test Example 2-1;

FIG. 6A is an SEM surface image of the TiO₂/FTO substrate obtained in Test Example 2-1;

FIG. 6B is an SEM cross-sectional image of the TiO₂/FTO substrate obtained in Test Example 2-1;

FIG. 7 is a TEM image and an electron diffraction image of a titanium oxide crystal obtained in Test Example 2-1;

FIG. 8 shows an absorbance spectrum of a dye-sensitized agent SMP-109 and an IPCE spectrum of a photoelectric conversion element in Test Examples 1-1 and 2-1 using the dye-sensitized agent SMP-109;

FIG. 9 is a graph showing a measurement result of photocurrent of the photoelectric conversion element in Test Examples 1-1 and 2-1;

FIG. 10 is a graph showing a relationship between an energy level and IPCE of LUMO of the dye-sensitized agent used in the photoelectric conversion elements in Test Examples 1-1 and 2-1;

FIG. 11A is an SEM surface image of an anatase-type TiO₂/rutile-type TiO₂ substrate obtained in Test Example 2-2;

FIG. 11B is an SEM surface image of an anatase-type TiO₂/rutile-type TiO₂ substrate obtained in Test Example 2-2;

FIG. 11C is an SEM surface image of an anatase-type TiO₂/rutile-type TiO₂ substrate obtained in Test Example 2-2;

FIG. 11D is an SEM perspective image of a TiO₂/FTO substrate obtained in Test Example 2-2;

FIG. 12A is an SEM surface image of a TiO₂/FTO substrate obtained in Test Example 2-3;

FIG. 12B is an SEM surface image of a TiO₂/FTO substrate obtained in Test Example 2-3;

FIG. 13 is an SEM surface image of a TiO₂/FTO substrate obtained in Test Example 2-4;

FIG. 14 is an SEM surface image of a TiO₂/FTO substrate obtained in Test Example 2-5;

FIG. 15 is an SEM surface image of a TiO₂/FTO substrate obtained in Test Example 2-6;

FIG. 16 is an SEM surface image of a TiO₂/FTO substrate obtained in Test Example 2-7;

FIG. 17 is an SEM surface image of a TiO₂/FTO substrate obtained in Test Example 2-8;

FIG. 18 is an SEM surface image of a TiO₂/FTO substrate obtained in Test Example 3-4;

FIG. 19A is a graph showing a relationship between an F/Ti molar ratio and a (001) face ratio in Test Examples 2-1, 3-1A to 3-1D, 3-2A, 3-2B, and 3-3;

FIG. 19B is a graph showing a relationship between an F/Ti molar ratio and a (001) face ratio in Test Examples 2-1, 3-1A to 3-1D, 3-2A, 3-2B, 3-3, and 3-4;

FIG. 20 is a graph showing a relationship between an F/Ti molar ratio and an average diameter of a top face of a plate-like crystal in a longitudinal direction in Test Examples 2-1, 3-1A to 3-1D, 3-2A, 3-2B, and 3-3;

FIG. 21 is a graph showing a relationship between an F/Ti molar ratio and an actual surface area/substrate projected area in Test Examples 2-1, 3-1A to 3-1D, 3-2A, 3-2B, and 3-3;

FIG. 22 is an SEM cross-sectional image of a TiO₂/FTO substrate obtained in Test Example 4-2; and

FIG. 23 is a graph showing a measurement result of photocurrent of a photoelectric conversion element in Test Examples 4-1 and 4-2.

### DESCRIPTION OF EMBODIMENTS

Hereinafter, the present invention shall be explained in detail.

### [Titanium Oxide Laminated Film]

A titanium oxide laminated film according to the present invention includes:

a first titanium oxide film that consists of a plurality of anatase-type plate-like crystals, (001) faces of the anatase-type plate-like crystals are grown in a vertical direction or an inclined direction with respect to a deposition surface of a base material; and

a second titanium oxide film that has a specific area greater than a specific surface area of the first titanium oxide film and consists of a plurality of titanium oxide fine particles,

in which the first titanium oxide film and the second titanium oxide film are sequentially laminated on the base material.

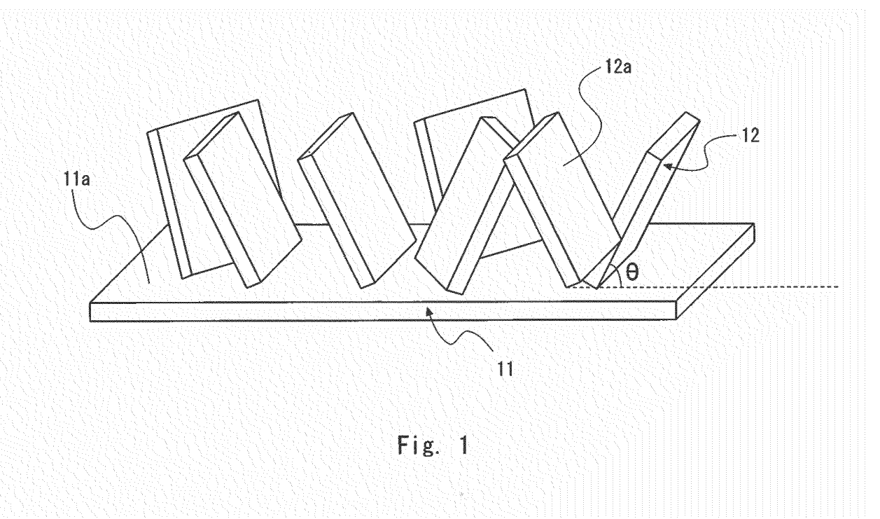

FIG. 1 is an image perspective diagram of a first titanium oxide film in the titanium oxide laminated film of the present invention.

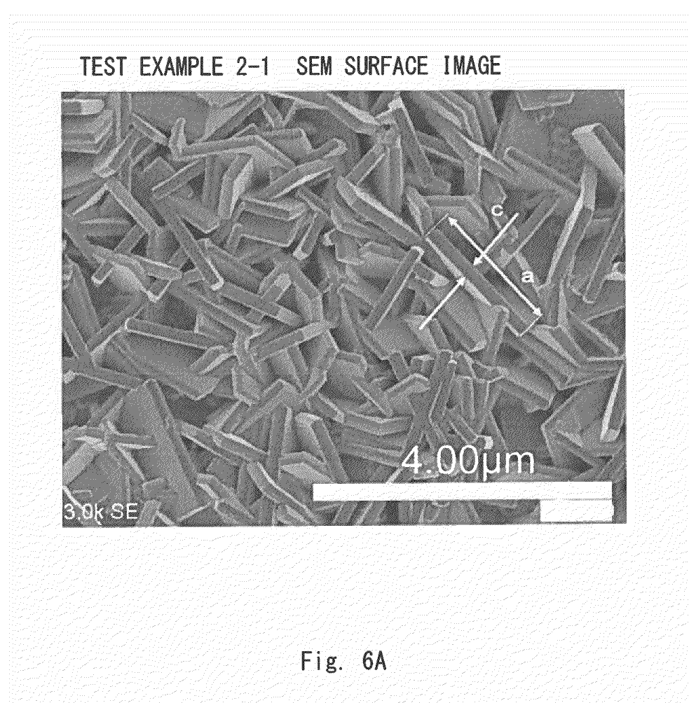

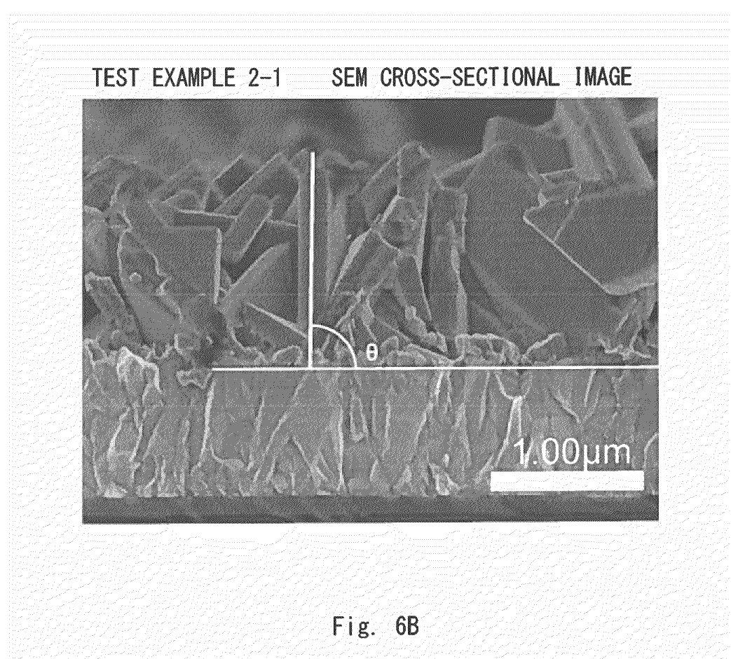

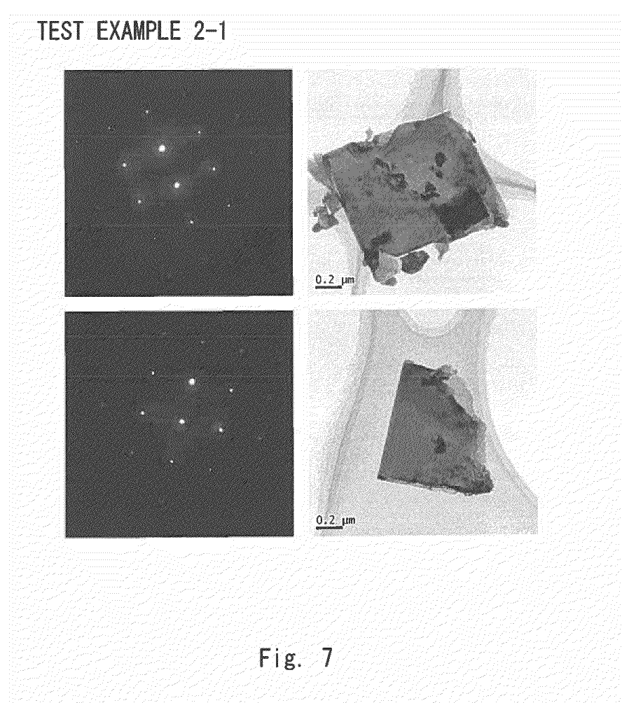

FIG. 1 is created based on SEM images (FIGS. 6A and 6B) in Test Example 2-1, which will be explained later.

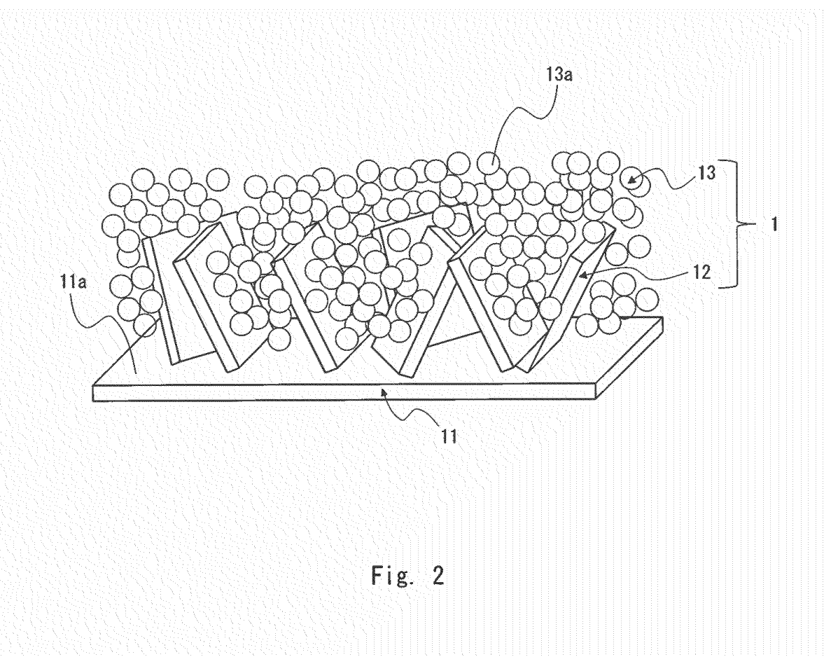

FIG. 2 is an image perspective diagram of a titanium oxide laminated film of the present invention.

FIG. 2 shows a state in which a second titanium oxide film 13 consisting of a titanium oxide fine particle film is laminated on the first titanium oxide film shown in FIG. 1.

In the drawings, a code 1 indicates the titanium oxide laminated film, a code 11 indicates a base material, a code 11a indicates a deposition surface of the base material, a code 12 indicates the first titanium oxide film consisting of anatase-type plate-like crystals, a code 12a indicates a (001) face of the anatase-type crystal, a code 13 indicates a second titanium oxide film consisting of a titanium oxide fine particle film, and a code 13a indicates a titanium oxide fine particle.

For example, as shown in FIG. 2, the titanium oxide fine particles 13a fill in gaps of the first titanium oxide film 12 consisting of a plurality of plate-like crystals in which the (001) faces are grown in a vertical direction or an inclined direction with respect to the deposition surface 11a of the base material 11, and the titanium oxide fine particles are deposited on the deposition surface 11a of the substrate 11.

The titanium oxide film consisting of anatase-type plate-like crystals and the titanium oxide laminated film including the titanium oxide film consisting of anatase-type plate-like crystals and a titanium oxide fine particle film can be favorably used as a semiconductor film for supporting a dye-sensitized agent in a dye-sensitized type photoelectric conversion element.

There is no special limitation on the base material. The first titanium oxide film can be grown on any base material, and the second titanium oxide film can be laminated on the first titanium oxide film.

For example, when the titanium oxide film is used as a semiconductor film for supporting a dye-sensitized agent in a dye-sensitized photoelectric conversion element, it is preferable to use a base material in which a translucent conductive film consisting of FTO (Fluorine-doped Titanium Oxide), ITO (Indium Tin Oxide) or the like is formed on a translucent substrate formed of glass, PET (polyethylene terephthalate) or the like.

A nano-order titanium oxide fine particle film that has been generally used alone in related arts is unable to achieve high conductivity due to an interface resistance between particles and has a relatively poor electron-injection efficiency and electron transfer property.

As the first titanium oxide film consisting of anatase plate-like crystals is a single-crystal film, the first titanium oxide film has good conductivity and is excellent in electron-injection efficiency and electron transfer property as compared to the nano-order titanium oxide fine particle film that has been generally used in related arts.

There are several crystal faces in the anatase-type titanium oxide.

In the anatase-type titanium oxide crystals, as (001) faces have a high chemical activity, they are unstable and difficult to grow. However, because of the high chemical activity of the (001) faces, by preferentially growing the (001) faces, it is possible to obtain a semiconductor film with a high chemical activity, electron-injection efficiency, and electron transfer property.

Further, when the (001) faces of the anatase-type titanium oxide crystals are preferentially grown on the base material, it is possible to obtain a high quality single-crystal film that is excellent in surface smoothness, has reduced crystal interfaces or crystal faults and a high electron-injection efficiency and electron transfer property in comparison to the titanium oxide crystals in which the faces (101) are preferentially grown.

As the (001) faces of the first titanium oxide film are preferentially grown, when the first titanium oxide film is used as a semiconductor film for supporting a dye-sensitized agent in a dye-sensitized type photoelectric conversion element, a high photoelectric conversion property can be expected in comparison to when other crystal faces of the first titanium oxide film are preferentially grown.

When the first titanium oxide film is used as a semiconductor film for supporting a dye-sensitized agent in a dye-sensitized type photoelectric conversion element, it is possible to realize photoelectric conversion in an infrared region (a wavelength region of 700 to 900 nm) which is considered to be a difficult region for photoelectric conversion in related arts. Details of the photoelectric conversion in the infrared region shall be explained later.

As the (001) faces of the first titanium oxide film are grown in the vertical direction or the inclined direction with respect to the deposition surface of the base material, the dye-sensitized agent can be supported. If the (001) faces are grown in a direction parallel with respect to the deposition surface of the base material, there will be no gap in the surface of the film for supporting the dye-sensitized agent.

However, as the first titanium oxide film consists of a plurality of plate-like crystals, a specific surface area of the first titanium oxide film is, for example, one order of magnitude smaller than a specific surface area of the nano-order titanium oxide fine particle film that has been used generally in related arts.

In the present invention, by using the first titanium oxide film in combination with the second titanium oxide film, it is possible to increase the entire specific surface area in comparison to when the first titanium oxide film is used alone.

Therefore, when the titanium oxide laminated film is used as a semiconductor film for supporting a dye-sensitized agent in a dye-sensitized agent type photoelectric conversion element, it is possible to provide a dye-sensitized agent type photoelectric conversion element that can increase the amount of the dye-sensitized agent to be supported and is excellent in a photoelectric conversion property.

In consideration of the specific surface area, an angle θ of the (001) face with respect to the deposition surface of the base material is preferably large, and to be more specific, the angle is preferably 10° or greater, more preferably 30° or greater, and especially preferably 60° or greater.

The present inventors has succeeded in making the inclined angle θ of the (001) face with respect to the deposition surface of the base material be in the range of 30 to 90° and supporting the dye-sensitized agent (see the following section [Example]).

In consideration of the chemical activity of the first titanium oxide film, a ratio (the (001) face ratio) of the area of the (001) faces to a total area of all crystal faces of anatase-type crystals is preferably large.

By making various changes in deposition conditions, the (001) face ratio can be greater than about 5%, which is a ratio normally reported, specifically, the (001) face ratio can be, for example, greater than or equal to 10%. The (001) face ratio is preferably 30% or greater, more preferably 50% or greater, and especially preferably 80% or greater. The present inventors has succeeded in making the (001) face ratio be in the range of, for example, 30 to 92% (see the following section [Example]).

A particle diameter of the titanium oxide fine particles constituting the second titanium oxide film is not especially limited, but preferably in the range of, for example, about 5 to 20 nm in applications such as a dye-sensitized type photoelectric conversion element.

The crystal type of the second titanium oxide film is not especially limited, but is preferably the anatase-type in applications such as a dye-sensitized type photoelectric conversion element.

### (Manufacturing Method of First Titanium Oxide Film)

The first titanium oxide film consisting of anatase-type plate-like crystals can be manufactured by a liquid-phase process using a titanium oxide liquid precursor that includes a titanium oxide precursor as an essential component and may include an additive agent as an optional component.

As the titanium oxide liquid precursor,

a titanium oxide liquid precursor containing at least one of:

a titanium oxide precursor containing an element for reducing a chemical activity of the (001) face of the anatase-type titanium oxide crystals;

a non-acidic additive agent containing an element for reducing a chemical activity of the (001) face of the anatase-type titanium oxide crystals; and

a non-acidic additive agent consisting of a compound for reducing a chemical activity of the (001) face of the anatase-type titanium oxide crystals,

is preferable.

When the above-mentioned titanium oxide liquid precursor of the present invention is used, the chemical activity of the unstable (001) faces with a high chemical activity is reduced and stabilized, thereby preferentially growing the (001) faces.

Although the mechanism for reducing the chemical activity of the (001) faces is not necessarily clear, it is considered that, for example, a particular element or compound absorbs to the (001) faces or a particular element or compound acts on the (001) faces, thereby reducing the surface energy.

As the element for reducing the chemical activity of the (001) faces of the anatase-type titanium oxide crystals, there are, for example, a halogen such as elemental fluorine (F) or elemental chlorine (Cl), and elemental fluorine (F) or the like is especially preferable. One, two, or more kinds of these elements can be used.

As the fluorine-containing titanium oxide precursor, there are, for example, TiF₄ and a salt of [TiF₆]²⁻ or the like. One, two, or more kinds of these precursors can be used.

A halogen-containing titanium oxide precursor can be used in combination with a non-halogen-containing titanium oxide precursor.

As the non-halogen-containing titanium oxide precursor, there are, for example, titanium tetrabutoxide, titanium tetraisopropoxide, sopropoxide, titanium tetrachloride, and titanium sulfate. One, two, or more kinds of these precursors can be used.

Instead of or together with the halogen-containing titanium oxide precursor, a non-acidic additive agent containing a halogen can be used, and a non-acidic additive agent containing an elemental fluorine is preferably used.

When the halogen-containing titanium oxide precursor is not used, the halogen-containing titanium oxide precursor such as the one exemplified above is essential.

As the non-acidic additive agent containing an elemental fluorine, there are, for example, ammonium fluoride, ammonium hydrogen fluoride, a salt of [BF₄]⁻, and a salt of [PF₆]⁻. One, two, or more kinds of these additive agents can be used.

The present inventors has found that by using the non-acidic additive agent consisting of a salt of [BF₄]⁻ and/or a salt of [PF₆]⁻, the (001) face ratio can be improved (see the following section [Example]). The reason why the (001) face ratio can be improved is not clear, however it can be presumed that as a salt of [BF₄]⁻ and/or a salt of [PF₆]⁻ absorb to the deposition surface, the growth of the (001) faces is promoted.

The present inventors has also found that by using the non-acidic additive agent consisting of a salt of [BF₄]⁻ and/or a salt of [PF₆]⁻, the actual surface area/substrate projected area can be improved (see the following section [Example]).

The additive amount of a salt of [BF₄]⁻ and/or a salt of [PF₆]⁻ is preferably 0.2 M or greater, and preferably in the range of, for example, 0.2 to 0.4 M.

Non-Patent Literature 1 mentioned in the section “Background Art” does not disclose the addition of a salt of [BF₄]⁻ and/or a salt of [PF₆]⁻ and improvement of the (001) face ratio and the actual surface area/substrate projected area because of the addition.

In applications such as a dye-sensitized type photoelectric conversion element, hydrofluoric acid may melt a metal oxide such as FTO or ITO, which is common as a foundation of a titanium oxide film.

As the present invention does not necessarily require an acid additive agent, the present invention is preferable for an application of depositing a titanium oxide film on a foundation which is weak against an acid such as FTO or ITO.

In the titanium oxide liquid precursor, the amount of the halogen such as F to Ti is not especially limited but preferably 0.1 to 20 times as great as the molar ratio of the F element to the Ti element (F/Ti).

As the non-acidic additive agent consisting of the compound for reducing the chemical activity of the (001) faces of the anatase-type titanium oxide crystals, an alcohol such as polyvinyl alcohol (PVA) and an amine such as diethylenetriamine can also be used. One, two, or more kinds of these additive agents can be used.

Non-Patent Literature 1 mentioned in the section “Background Art” does not disclose such an addition.

As the preferential growth of the (001) faces proceeds at a higher level, it is preferable to use a fluorine-containing titanium oxide precursor and/or a non-acidic additive agent containing fluorine.

Since the preferential growth of the (001) faces proceeds at a high-level and it is not necessary to further add an additive agent for reducing the chemical activity of the (001) faces, it is especially preferable to use a fluorine-containing titanium oxide precursor.

As the preferential growth of the (001) faces proceeds at a higher level, it is especially preferable to use a salt of [TiF₆]²⁻ among fluorine-containing titanium oxide precursors.

It is most preferable to use a salt of [TiF₆]²⁻, which is a fluorine-containing titanium oxide precursor in combination with a salt of [BF₄]⁻ and/or a salt of [PF₆]⁻, which are non-acidic additive agents. By using a titanium oxide liquid precursor having the above-mentioned composition, the first titanium oxide film having a large (001) face ratio and actual surface area/substrate projected area can be manufactured.

The titanium oxide liquid precursor of the present invention contains an inorganic solvent such as water and/or an organic solvent. Further, the titanium oxide liquid precursor of the present invention may contain one, two, or more kinds of any other additive agents.

A pH of the titanium oxide liquid precursor is not especially limited and selected according to a base material which will be used. The pH of the titanium oxide liquid precursor of the present invention is preferably within, at least, a pH range in which the solubility to the foundation for depositing the titanium oxide film is low.

The rear surface of the base material, which is the opposite side of the deposition surface, can be protected by a protective film or the like as necessary.

Once again, for example, in an application of a dye-sensitized type photoelectric conversion element, an acidic titanium oxide liquid precursor may melt a metal oxide such as FTO or ITO, which is common as a foundation of a titanium oxide film. Accordingly, when the foundation is a metal oxide such as FTO or ITO, the pH of the titanium oxide liquid precursor is more preferable to be non-acidic.

In the following section [Example], although an acidic liquid containing hydrochloric acid is used as the titanium oxide liquid precursor, hydrochloric acid is not an essential component.

In the present invention, as the acidic additive agent such as hydrofluoric acid is not used as the additive agent for reducing the chemical activity of the (001) faces of the anatase-type titanium oxide crystals, the liquid precursor can be non-acidic.

Further, the titanium oxide liquid precursor in the following section [Example] has a prescription that does not cause deterioration of conductivity of a foundation conductive film.

As the liquid-phase process using the titanium oxide liquid precursor, there is, for example, the hydrothermal synthesis method that uses water as a solvent. An organic solvent may be used in the liquid-phase process.

A reaction temperature in the hydrothermal synthesis method is not especially limited and is sufficient at, for example, 250° C. or lower. For example, the preferable reaction temperature is in the range of 150 to 250° C. As described later, calcination can be performed after synthesis as necessary, however the calcination, which is a post-process, is not essential.

Therefore, there is a wide range of choice for a base material that can be used, which is preferable. Not only an inorganic material with a high heat-resistance property but also an organic material such as a resin can be used as the substrate or the foundation of deposition.

In the hydrothermal synthesis method, it is preferable to perform microwave irradiation for shortening the reaction time and for uniform growth of crystals.

Without the microwave irradiation, normally the reaction time for ten hours or more is required. By performing the microwave irradiation, only 45 to 90 minutes of the reaction time is required.

Note that Non-Patent Literature 1 mentioned in the section “Background Art” does not disclose the microwave irradiation.

The frequency of the microwave is not especially limited but preferably in the range of, for example, 0.1 to 50 GHz because the titanium oxide liquid precursor can be favorably heated in that range.

After the liquid-phase synthesis, the first titanium oxide film consisting of anatase-type plate-like crystals in which the (001) faces are grown in the vertical direction or the inclined direction with respect to the deposition surface of the base material can be obtained. After the liquid-phase synthesis, the obtained titanium oxide film can be calcined as necessary. By the calcination, a solvent such as water and an inorganic solvent and impurities can be removed.

When the titanium oxide laminated film of the present invention is used as a semiconductor film for supporting a dye-sensitized agent in a dye-sensitized agent type photoelectric conversion element, and there is an elemental fluorine on the surface of the first titanium oxide film, the dye-sensitized agent may not be favorably supported. Therefore, in the above-mentioned application, when the fluorine-containing titanium oxide precursor and/or the additive agent containing an elemental fluorine is used in the liquid precursor, it is preferable to remove the elemental fluorine by calcination. Normally, the elemental fluorine can be removed by calcination at 500° C. or higher.

As a result of an investigation by the present inventors, there was no change in the membrane structure even when the first titanium oxide film in which the (001) faces of the anatase-type crystals are grown in the vertical direction or the inclined direction with respect to the deposition surface of the base material, which has been obtained after the liquid-phase synthesis, was calcined.

Depending on the application, a solvent, an elemental fluorine or the like may remain. Further, the base material may not be heat-resistant at 500° C. or higher. In such a case, the calcination may be performed at a lower temperature than 500° C., or the calcination may not be performed.

Liquid-phase process is less costly than vapor-phase process. Further, in the above-mentioned manufacturing method, as the (001) faces of the anatase-type crystals can be preferentially grown directly on the base material, and the first titanium oxide film having a desired membrane structure can be deposited, only a small number of processes are required, thereby leading to a low cost and facilitating control of the crystal orientation.

### (Manufacturing Method of Second Titanium Oxide Film)

The manufacturing method of the second titanium oxide film of the titanium oxide laminated film according to the present invention is not especially limited, and it is possible to use manufacturing methods of the titanium oxide fine particle film for supporting the dye-sensitized agent that has been used in related arts.

There is, for example, the sol-gel process in which a sol or the like containing a titanium oxide precursor is coated and calcination is performed.

See the following section [Example] for the specific process.

### “Titanium Oxide Film, Titanium Oxide Liquid Precursor, Manufacturing Method of Titanium Oxide Film”

Some of the first titanium oxide films of the titanium oxide laminated films and some of the titanium oxide liquid precursors that are used in the manufacturing of the titanium oxide laminated film are new themselves and included in the present invention.

A manufacturing method of the titanium oxide film using the above-mentioned titanium oxide liquid precursor is also new and included in the present invention.

A titanium oxide film according to the present invention is a titanium oxide film that is formed on a base material and consisting of a plurality of anatase-type plate-like crystals having (001) faces grown in a vertical direction or an inclined direction with respect to a deposition surface of the base material, in which

an inclined angle of the (001) faces with respect to the deposition surface is 10° or greater,

a ratio of areas of the (001) faces to a total area of all crystal faces of the anatase-type crystals is 10% or greater, and

an actual surface area/substrate projected area is 20 or greater.

A first titanium oxide liquid precursor according to the present invention is a titanium oxide liquid precursor that is used for depositing a titanium oxide film consisting of a plurality of anatase-type plate-like crystals having (001) faces grown in a vertical direction or an inclined direction with respect to a deposition surface of a base material, the first titanium oxide liquid precursor including:

a titanium oxide precursor; and

a non-acidic additive agent consisting of a salt of [BF₄]⁻ and/or a salt of [PF₆]⁻.

A second titanium oxide liquid precursor according to the present invention is a titanium oxide liquid precursor that is used for depositing a titanium oxide film consisting of a plurality of anatase-type plate-like crystals having (001) faces grown in a vertical direction or an inclined direction with respect to a deposition surface of a base material, the second titanium oxide liquid precursor including:

a titanium oxide precursor; and

a non-acidic additive agent consisting of an alcohol and/or an amine.

A method of manufacturing a titanium oxide film consisting of a plurality of anatase-type plate-like crystals in which (001) faces are grown in a vertical direction or an inclined direction with respect to a deposition surface of a substrate, the method including:

depositing the titanium oxide film by a liquid-phase process using the above-mentioned first or second titanium oxide liquid precursor according to the present invention.

### [Dye-Sensitized Agent Type Photoelectric Conversion Element]

A first dye-sensitized agent type photoelectric conversion element of the present invention includes:

a base material and a semiconductor film that supports a dye-sensitized agent,

in which the semiconductor film includes the above-mentioned titanium oxide laminated film of the present invention.

The first dye-sensitized agent type photoelectric conversion element of the present invention includes an anatase-type first titanium oxide film that consists of a single-crystal film as the semiconductor film for supporting the dye-sensitized agent, has the (001) faces that are preferentially grown, a high chemical activity, and a favorable electron-injection efficiency and electron transfer property and a second titanium oxide film that consists of a titanium oxide fine particle film having a specific surface area greater than the first titanium oxide film. Therefore, according to the present invention, it is possible to provide a dye-sensitized agent type photoelectric conversion element that is excellent in a photoelectric conversion property.

The second dye-sensitized agent type photoelectric conversion element of the present invention includes:

a base material; and

a semiconductor film that supports the dye-sensitized agent,

in which the semiconductor film includes the above-mentioned titanium oxide film consisting of anatase-type plate-like crystals of the present invention.

As the above-mentioned titanium oxide film consisting of anatase-type plate-like crystals has a high (001) face ratio and actual surface area/substrate projected area, by using the titanium oxide film, it is possible to provide the dye-sensitized agent type photoelectric conversion element that is excellent in a photoelectric conversion property.

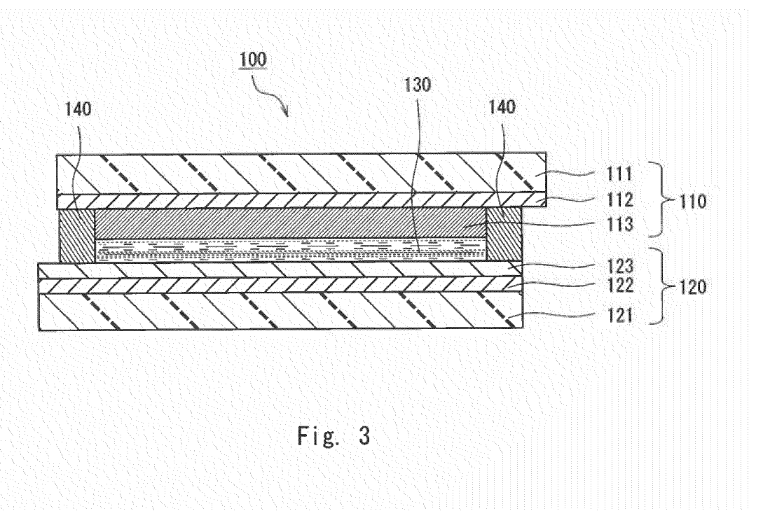

An embodiment of the dye-sensitized type photoelectric conversion element shall be explained with reference to the drawings. FIG. 3 is a schematic cross-sectional diagram.

A dye-sensitized type photoelectric conversion element 100 of this embodiment is generally composed of:

a negative electrode substrate 110 in which a first conductive film 112 consisting of FTO (Fluorine-doped Titanium Oxide), ITO (Indium Tin Oxide) or the like and a semiconductor film 113 that supports a dye-sensitized agent are sequentially formed as a negative electrode on a surface of a first substrate 111, which is formed of a glass substrate or the like;

a positive electrode substrate 120 in which a second conductive film 122 consisting of FTO, ITO or the like and a catalyst layer 123 such as platinum are sequentially formed as a positive electrode on a surface of a second substrate 121, which is formed of a glass substrate or the like; and

an electrolyte layer 130 that is filled between the negative electrode substrate 110 and the positive electrode substrate 120 and contains a redox pair.

The first conductive film 112, which is the negative electrode side, and the second conductive film 122, which is the positive electrode side, are electrically connected via an external circuit.

As the electrolyte layer 130, a redox solution containing iodine or the like is used.

A peripheral part of the dye-sensitized type photoelectric conversion element 100 is sealed by a seal material 140.

For the dye-sensitized type photoelectric conversion element 100, the semiconductor film 113 is formed of the above-mentioned titanium oxide laminated film of the present invention (the laminated film including the first titanium oxide film consisting of anatase-type plate-like crystals in which the (001) faces are grown in the vertical direction or the inclined direction with respect to the deposition surface and the second titanium oxide film consisting of the titanium oxide fine particle film) or the titanium oxide film consisting of anatase-type plate-like crystals in which the (001) faces are grown in the vertical direction or the inclined direction with respect to the deposition surface.

The dye-sensitized agent is not especially limited, and one, two, or more kinds of known dye-sensitized agents can be used.

In the dye-sensitized type photoelectric conversion element 100, the first substrate 111 and the first conductive film 112, which are the negative electrode side, need to be translucent. The second substrate 121 and the second conductive film 122, which are the positive electrode side, may be translucent or may not be translucent.

In the dye-sensitized photoelectric conversion element 100, electrons of the dye-sensitized agent are excited by light entered from the first substrate 111 side, which is the negative electrode side, and the excited electrons are conducted to the titanium oxide that supports the dye-sensitized agent, and further conducted to the first conductive film 112. The electrons conducted to the first conductive film 112 are conducted to the second conductive film 122, which is the positive electrode side, via the external circuit. The electrons conducted to the second conductive film 122, which is the positive electrode side, return to a ground level of the dye-sensitized agent via the redox pair in the electrolyte. Photoelectric conversion occurs by this series of actions.

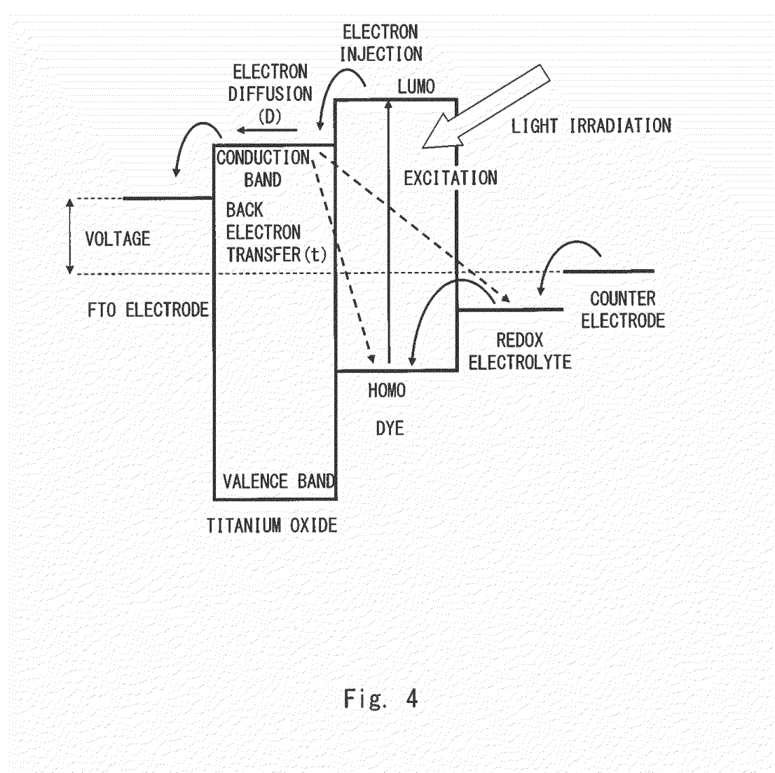

FIG. 4 schematically shows an energy diagram in the dye-sensitized photoelectric conversion element 100.

FIG. 4 illustrates an example in which the foundation of the titanium oxide film is an FTO electrode.

Electrons in HOMO (Highest Occupied Molecular Orbital) of the dye-sensitized agent are excited to LUMO (Lowest Unoccupied Molecular Orbital) by light entered in the dye-sensitized agent. Then, the electrons are injected into a conduction band of the titanium oxide from LUMO of the dye-sensitized agent.

The electrons injected into the conduction band of the titanium oxide are diffused and conducted to the first conductive film such as FTO. The electrons are conducted to a counter electrode side via the external circuit and return to the ground level of the dye-sensitized agent via the redox pair in the electrolyte.

In order to inject the electrons in LUMO of the dye-sensitized agent into the titanium oxide, it is necessary that the energy level of the conduction band of the titanium oxide is lower than the energy level of LUMO of the dye-sensitized agent. The greater a difference (LUMO-conduction band gap) ΔE1 between the energy level of LUMO of the dye-sensitized agent and the energy level of the conduction band of the titanium oxide is, the more likely the electrons transfer.

The energy level of the conduction band of the titanium oxide is about −0.5 eV (vs NHE).

A difference (HOMO-LUMO gap) of the energy levels of HOMO and LUMO in the dye-sensitized agent corresponds to a wavelength of light which will be absorbed. The longer the wavelength of the light which will be absorbed, the more likely the HOMO-LUMO gap becomes smaller.

As for the dye-sensitized agent for absorbing visible light having a wavelength of 400 to 700 nm, the HOMO-LUMO gap can be made sufficiently large, thereby enabling the LUMO-conduction band gap ΔE1 to be sufficiently large.

Meanwhile, as for the dye-sensitized agent for absorbing infrared light having a wavelength of 700 to 900 nm, as the HOMO-LUMO gap is small, the LUMO-conduction band gap ΔE1 cannot be made sufficiently large. When the dye-sensitized agent for absorbing infrared light is used, normally the LUMO-conduction band gap ΔE1 is 0.2 eV (vs NHE) or less.

In related arts, when it is ΔE1≦0.2 eV (vs NHE), as the injection efficiency of the excited electrons of the dye-sensitized agent into the titanium oxide remarkably deteriorates, photoelectric conversion is considered to be difficult.

Therefore, in the dye-sensitized photoelectric conversion element of related arts, generally photoelectric conversion in the visible region is considered to be relatively easy, while photoelectric conversion in the infrared region is considered to be difficult even by using the dye-sensitized agent that indicates absorption in the infrared region.

The dye-sensitized agent type photoelectric conversion element of the present invention includes the titanium oxide film that consists of a single-crystal film consisting of anatase-type plate-like crystals in which the (001) faces are preferentially grown, has a high chemical activity, and has a favorable electron-injection efficiency and electron transfer property.

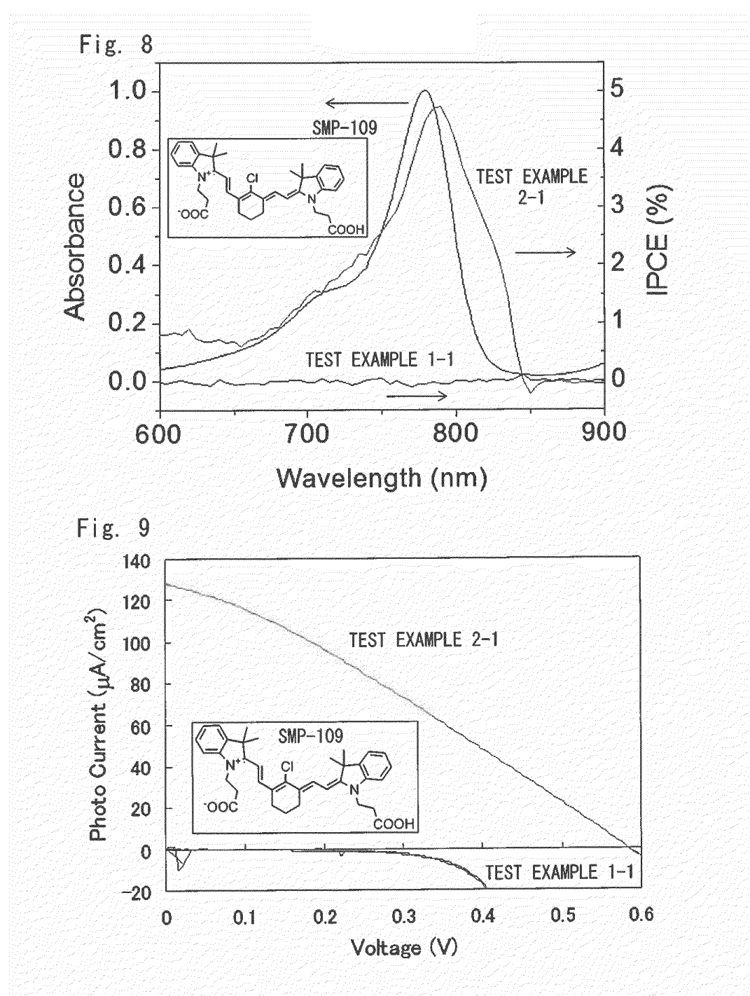

Therefore, according to the present invention, when a dye-sensitized agent indicating absorption in the infrared region is used it is possible to provide a dye-sensitized type photoelectric conversion element that indicates a photoelectric conversion response in the infrared region even under the condition where it is ΔE1≦0.2 eV (see the following section [Example] and FIGS. 8 and 9). This is considered to be because that in the crystals of the titanium oxide film consisting of anatase-type plate-like crystals, the (001) faces with a high chemical activity are grown more than normal, thereby improving the electron injection property of the excited electrons of the dye-sensitized agent that are absorbed to the faces into the titanium oxide.

As described above, when the dye-sensitized agent indicating absorption in the visible region of 400 to 700 nm is used, ΔE1 can be made sufficiently large. Accordingly, with the present invention, when the dye-sensitized agent that indicates absorption in the visible region is used as the dye-sensitized agent, it is possible to provide a dye-sensitized type photoelectric conversion element that indicates the photoelectric conversion response in the visible region.

That is, according to the present invention, it is possible to provide the dye-sensitized type photoelectric conversion element that indicates the photoelectric conversion response in the visible region and the infrared region. As the wavelength region of light which can be used is increased, an improvement in the photoelectric conversion efficiency can be expected.

In this case, one or a plurality of kinds of dye-sensitized agents that have absorption in both of the visible region and the infrared region may be used. Alternatively, one or a plurality of kinds of dye-sensitized agents that have absorption in the visible region may be used together with one or a plurality of kinds of dye-sensitized agents that has absorption in the infrared region.

For example, in the titanium oxide film consisting of anatase-type plate-like crystals, dye-sensitized agents with different absorption wavelengths can be mixed and supported.

The dye-sensitized agents with different absorption wavelengths can be supported to different crystal faces of the titanium oxide film consisting of anatase-type plate-like crystals.

When the titanium oxide film consisting of anatase-type plate-like crystals is used in combination with and the titanium oxide fine particle film, one or a plurality of kinds of dye-sensitized agents that have absorption in the infrared region can be supported in the titanium oxide film consisting of anatase-type plate-like crystals, and one or a plurality of kinds of dye-sensitized agents that have absorption in the visible region can be supported in the titanium oxide fine particle film.

The dye-sensitized agent type photoelectric conversion itself that includes the titanium oxide film consisting of anatase-type plate-like crystals alone as the semiconductor film for supporting the dye-sensitized agent, uses a dye-sensitized agent that indicates absorption in the wavelength region of 700 to 900 nm as the dye-sensitized agent, and indicates the photoelectric conversion response in the wavelength of 700 to 900 nm is new and included in the present invention.

As explained above, according to the present invention, it is possible to provide the titanium oxide laminated film that includes the titanium oxide film consisting of anatase-type plate-like crystals in which the (001) faces with a high chemical activity are grown more than normal and the (001) faces are grown in the vertical direction or the inclined direction with respect to the deposition surface of the base material, and is capable of having a specific surface area greater than that of the titanium oxide film alone.

According to the present invention, it is possible to provide the titanium oxide laminated film that includes the titanium oxide film consisting of anatase-type plate-like crystals in which the (001) faces having a high chemical activity are grown more than normal and the faces (100) are grown in the vertical direction or the inclined direction with respect to the deposition surface of the base material, is capable of supporting the dye-sensitized agent, has a high chemical activity, a favorable electron-injection efficiency and electron transfer property, is capable of realizing a photoelectric conversion, when used in a dye-sensitized type photoelectric conversion element, and can be manufactured at a low cost, and a photoelectric conversion agent type photoelectric conversion element including the titanium oxide laminated film.

According to the present invention, it is possible to provide the titanium oxide film consisting of anatase-type plate-like crystals in which the (001) faces having a high chemical activity are grown more than normal and the (001) faces are grown in the vertical direction and the inclined direction with respect to the deposition surface of the base material, and an improved (001) face ratio and actual surface area/substrate projected area, the titanium oxide liquid precursor that is capable of manufacturing the titanium oxide film, and a manufacturing method of the titanium oxide film using the titanium oxide liquid precursor.

According to the present invention, it is possible to provide the dye-sensitized agent type photoelectric conversion element that is capable of realizing photoelectric conversion in the infrared region (the wavelength region of 700 to 900 nm).

### EXAMPLE

Test examples according to the present invention shall be explained.

### Test Example 1-1

### Deposition Base Substrate

An FTO substrate in which an FTO (Fluorine-doped Titanium Oxide) film having a thickness of 2 μm and a sheet resistance of 10 Ω/cm was formed by the CVD (Chemical Vapor Deposition) method was prepared. This FTO substrate was cleaned with water, acetone, and ethanol, and dried, and then organic substances were removed therefrom by ultraviolet ozone lamp irradiation, and the FTO substrate was used as the deposition base material.

### (Deposition of Titanium Oxide Fine Particle Film)

A sol (Ti sol manufactured by Solaronix) containing a titanium oxide precursor was coated on the deposition base material (FTO substrate), sintered for 30 minutes at 450° C., and a titanium oxide fine particle film having an average particle diameter of 10 nm and a thickness of 10 to 15 μm was formed. A dye-sensitized type photoelectric conversion element was obtained in a manner similar to that in the following Test Example 2-1 except that this was used as the negative electrode substrate.

### Test Example 2-1

### Deposition Base Material

The FTO substrate same as the one in Test Example 1-1 was used as a deposition base material.

### (Deposition of Titanium Oxide Film)

15 ml of 37 mass % hydrochloric acid solution and 15 ml of deionized water were mixed, and the solution was stirred for five minutes. 0.32 g of (NH₄)₂TiF₆ and 0.6 ml of Ti(OBu)₄ were added to this solution as the titanium oxide precursors, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 75 minutes at 210° C. while being irradiated with a microwave (2.45 GHz), and a titanium oxide film having a thickness of 3 to 4 nm was deposited by the hydrothermal synthesis method. After that, the deposition base material was air-cooled to a room temperature (20 to 25° C.).

The base material which had been subjected to the hydrothermal synthesis was retrieved and ultrasonically cleaned with pure water for 30 minutes.

The obtained TiO₂/FTO substrate was calcined in an air atmosphere in an electric furnace, and water which is a solvent, impurities, and an elemental fluorine were removed. The calcination profile was; five minutes at 325° C.→five minutes at 375° C.→15 minutes at 450° C.→15 minutes at 500° C.

In this test example, two kinds of precursors, which are (NH₄)₂TiF₆ and Ti(OBu)₄ were used as the titanium oxide precursor(s). Between these precursors, the former precursor contains an elemental fluorine for reducing the chemical activity of the (001) faces of the anatase-type crystals.

In this test example, an acid liquid containing hydrochloric acid was used as a liquid precursor, however hydrochloric acid is not an essential component, and the liquid precursor can be non-acidic.

### (Manufacturing Dye-Sensitized Type Photoelectric Conversion Element)

The obtained TiO₂/FTO substrate was immersed in a dye-sensitized agent solution which a dye-sensitized agent SMP-109 manufactured by Hayashibara Co., Ltd. was dissolved in a mixed solution of ethanol/t-butanol (capacity ratio 1/2) for twelve hours, and a negative electrode substrate was obtained. A chemical expression of the dye-sensitized agent that was used is shown in [Chemical Expression 1]. This dye-sensitized agent has absorption in the infrared region of 700 to 900 nm.

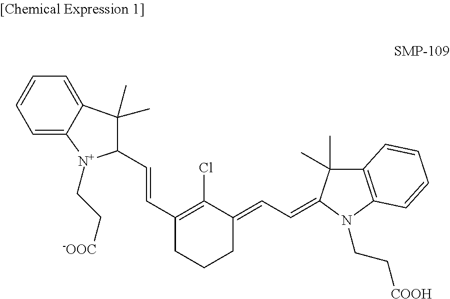

A sol (Platisol manufactured by Solaronix) containing a Pt precursor was coated on the same FTO substrate as the one used for the deposition base material of the titanium oxide film, the FTO substrate was calcined in an oxygen atmosphere at 450° C., so that platinum nanoparticles having a particle diameter of 1 to 5 nm were deposited on the surface of the substrate as a catalyzer, and a positive electrode substrate was obtained.

The above-mentioned negative electrode substrate and the positive electrode substrate were arranged to face each other so that the dye-supporting titanium oxide film and the Pt catalyst layer face each other, and peripheral parts of these substrates were thermally compressed using a thermoplastic resin (Surlyn manufactured by Solaronix) as a seal material. Next, an iodine-based electrolyte solution was injected between the electrodes, and a dye-sensitized photoelectric conversion element was obtained.

### <XRD Analysis>

An XRD (X-Ray Diffraction) analysis was performed on the FTO substrate and TiO₂/FTO substrate (calcined) obtained in Test Example 2-1.

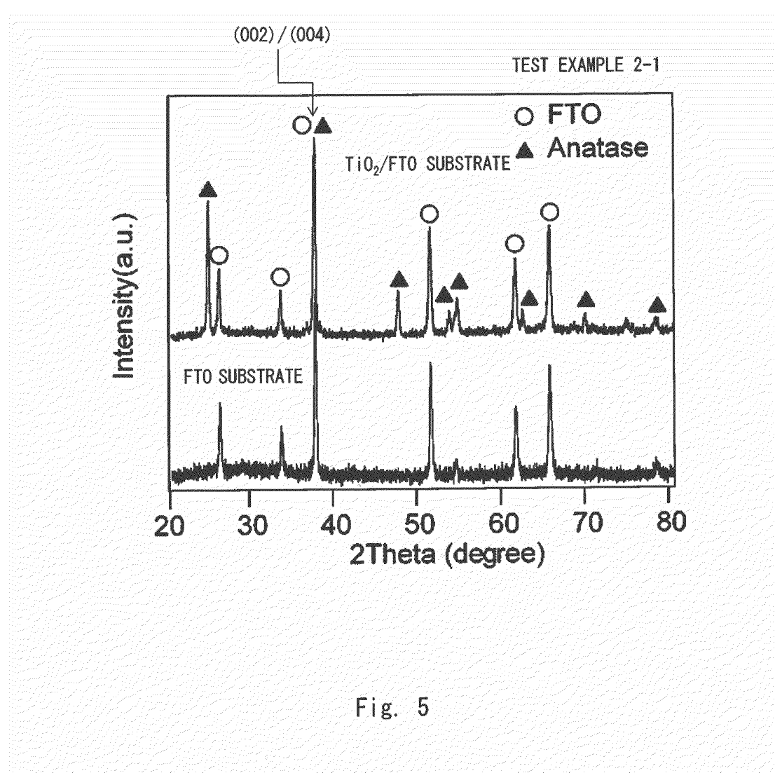

The obtained XRD pattern is shown in FIG. 5.

The titanium oxide film obtained in Test Example 2-1 was confirmed to be anatase-type crystals.

As described later, in the titanium oxide film in Test Example 2-1, the (001) faces were preferentially grown. The (001) orientation appears as a (002)/(004) peak in the XRD pattern. In this test example, as the (002)/(004) peak of the FTO substrate and (002)/(004) peak of the titanium oxide film are overlapped, an orientation degree could not be calculated.

### <SEM Observation and TEM Electron Ray Diffraction Analysis>

An SEM (Scanning Electron Microscope) observation was performed on the TiO₂/FTO (after cleaned with water and before calcined) obtained in Test Example 2-1.

An SEM surface image and an SEM cross-sectional image are shown in FIGS. 6A and 6B, respectively.

The obtained titanium oxide film consisted of plate-like crystals and had a membrane structure in which the (001) faces were grown in the vertical direction or the inclined direction with respect to the deposition surface of the base material.

The angle of the (001) face with respect to the deposition surface of the base material was in the range of 30 to 90°.

Further, the ratio (the (001) face ratio) of the areas of the (001) faces to a total area of all crystal faces of the anatase-type crystals was 83%.

Note that an SEM observation was performed also on the calcined titanium oxide film in a manner similar to above, however there was no change confirmed in the membrane structure before and after the calcination. This is indicated in that when the titanium oxide film having the membrane structure shown in FIGS. 6A and 6B was deposited directly on the base material by a hydrothermal synthesis reaction and then calcined, there was no change in the membrane structure.

A TEM electron ray diffraction analysis was performed on the titanium oxide film obtained in Test Example 2-1. A crystal sample was retrieved while performing a TEM (Transmission Electron Microscopy) observation, and an electron ray diffraction analysis was performed on a principal surface of the crystal sample. As a result of the analysis, it was confirmed that the crystal growth direction of the titanium oxide film was a [110] direction, and the principal surface (a square side face that was largely exposed) was the (001) face.

### <Measuring Specific Surface Area of Titanium Oxide Film>

A shape measurement was performed on 100 or more titanium oxide crystals from an SEM image of the titanium oxide film obtained in Test Example 2-1, and sizes of the titanium oxide crystals and inclined angles of the (001) faces with respect to the substrate surface were calculated by an actual measurement of SEM images of the titanium oxide crystals (illustrated in FIGS. 6A and 6B). As each titanium oxide crystal was formed in a substantially square shape, areas of the (001) and (101) faces were calculated based on particle diameters in an a-axis direction and a c-axis direction that were measured from the SEM image as shown in, for example, FIG. 6A. The evaluation method was the method disclosed in Non-Patent Literature 3 that is mentioned in the section “Background Art”. When the actual surface area/substrate projected area were calculated based on the result, the actual surface area/substrate projected area of the titanium oxide film in Test Example 2-1 were 17 (cm²/cm²). Normally, the specific surface area of the titanium oxide fine particle film in Test Example 1-1 was 500 to 1000 (cm²/cm²). Thus, the specific surface area of the titanium oxide film in Test Example 2-1 was one order of magnitude smaller than that of the titanium oxide fine particle film in Test Example 1-1.

### <Measuring SMP-109 Dye-Supporting Amount>

A dye-supporting amount was measured for each of the titanium oxide film in Test Example 2-1 and the titanium oxide fine particle film in Test Example 1-1. The dye-supporting amount was calculated by comparing a change in the absorbance of a SMP-109 dye solution before and after dye support. The result is shown below. The following data is the dye-supporting amount per substrate projected area.

The titanium oxide film in Test Example 2-1: 1.7×10⁻⁸ mol/cm²,
The titanium oxide fine particle film in Test Example 1-1: 2.48×10⁻⁷ mol/cm².

The dye-supporting amount of the titanium oxide film in Test Example 2-1 was a value one order of magnitude smaller than the dye-supporting amount of the titanium oxide fine particle film in Test Example 1-1. This result corresponds to the result of the specific surface area of the titanium oxide calculated above.

### <Evaluation of Photoelectric Conversion Property>

Using the spectral measurement response device (CEP-2000 manufactured by Bunkokeiki Co., Ltd.), an IPCE spectrum (a spectrum indicating a photoelectric conversion efficiency to a wavelength) was measured on the photoelectric conversion element in Test Examples 2-1 and 1-1 that uses the dye-sensitized agent SMP-109.

The result is shown in FIG. 8. FIG. 8 also shows an absorbance spectrum of the dye-sensitized agent SMP-109. In the photoelectric conversion element obtained in Test Example 1-1, even by using the dye-sensitized agent SMP-109 that has absorption in the infrared range (the wavelength region of 700 to 900 nm), a photoelectric conversion response in this wavelength region was not confirmed.

Meanwhile, in the photoelectric conversion element obtained in Test Example 2-1, a photoelectric conversion response in the infrared region was confirmed corresponding to the absorbance spectrum of the dye-sensitized agent SMP-109 that was used.

A measurement of photocurrent-voltage property was performed at a room temperature on the photoelectric conversion element in Test Examples 2-1 and 1-1 that used the dye-sensitized agent SMP-109 using pseudo sunlight (AM1.5, crystalline silicon standard, manufactured by Yamashita Denso Corporation).

The result is shown in FIG. 9.

In Test Example 1-1, photocurrent was 0 μA/cm² or less, and no photoelectric conversion response was confirmed in the infrared region. Meanwhile, in Test Example 2-1, photocurrent flows, and a photoelectric conversion response was confirmed in the infrared region.

In Test Examples 2-1 and 1-1, dye-sensitized type photoelectric conversion elements were obtained using different dye-sensitized agents, and an IPCE analysis was performed on each of the photoelectric conversion elements.

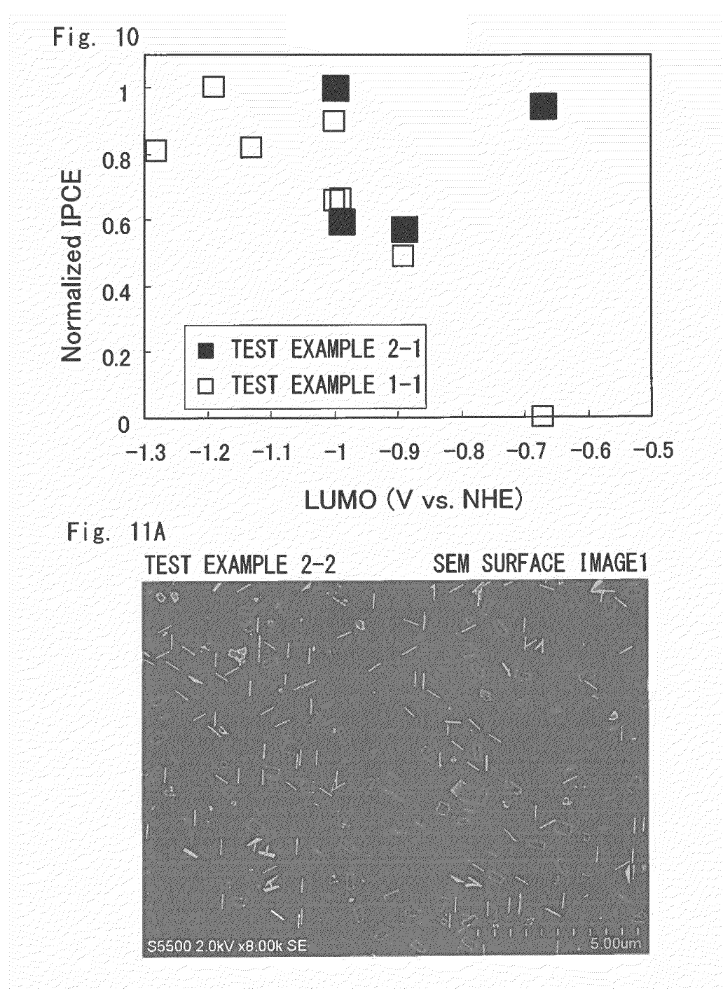

FIG. 10 shows a relationship between the energy level of LUMO of the dye-sensitized agent and IPCE at a peak top wavelength (e.g., 790 nm for SMP-109).

As described above, the titanium oxide film in Test Example 2-1 and the titanium oxide fine particle film in Test Example 1-1 had different specific surface areas. Specifically, the specific surface area of the titanium oxide fine particle film in Test Example 1-1 was one magnitude greater than that of the titanium oxide film in Test Example 2-1.

Thus, in Test Example 2-1, data was normalized in such a way that the greatest value of the IPCE of the sample in Test Example 2-1 is set to “1”, and the greatest value of the IPCE of the sample in Test Example 1-1 was set to “1”.

In the data in Test Examples 2-1 and 1-1 in FIG. 10, the data of the sample using the dye-sensitized agent that has absorption in the infrared region where the energy level of LUMO is 0.7 eV (vs NHE) or less is the data of the same sample as the sample, the data of which is shown in FIGS. 8 and 9.

In order to inject the electrons in LUMO of the dye-sensitized agent into the titanium oxide, it is necessary that the energy level of the conduction band of the titanium oxide is lower than the energy level of LUMO of the dye-sensitized agent. The greater a difference (LUMO-conduction band gap) ΔE1 between the energy level of LUMO of the dye-sensitized agent and the energy level of the conduction band of the titanium oxide is, the more likely the electrons transfer.

In related arts, when it is ΔE1≦0.2 eV (vs NHE), the photoelectric conversion has been considered to be difficult.

In related arts, as the conduction band of the titanium oxide is about −0.5 eV (vs NHE), when the energy level of LUMO of the dye-sensitized agent is 0.7 eV (vs NHE) or less, the photoelectric conversion has been considered to be difficult.

In Test Example 1-1, when the dye-sensitized agent that had absorption in the visible region where the energy level of LUMO is 0.9 eV (vs NHE) or greater was used, a photoelectric conversion response was confirmed. However when the dye-sensitized agent that had absorption in the infrared region where the energy level of LUMO was 0.7 eV (vs NHE) or less was used, no photoelectric conversion response was confirmed.

Meanwhile, in Test Example 2-1, a photoelectric conversion response was confirmed when either of the dye-sensitized agent that had absorption in the visible region where the energy level of LUMO is 0.9 eV (vs NHE) or greater and the dye-sensitized agent that had absorption in the near-infrared region where the energy level of LUMO was 0.7 eV (vs NHE) or less was used.

### Test Example 2-2

Test Example 2-2 is an example in which the deposition base substrate of the one in Test Example 2-1 was changed to a different one.

### (Deposition Base Material)

A rutile-type (110) single-crystal titanium oxide substrate was cleaned with water, acetone, and ethanol, and dried, and then organic substances were removed therefrom by ultraviolet ozone lamp irradiation, and the substrate was used as the deposition base material.

### (Deposition of Titanium Oxide Film)

The same liquid precursor as the one in Test Example 2-1 was produced, the hydrothermal synthesis was performed under the same conditions as those in Test Example 2-1, and an anatase-type titanium oxide film was deposited. After the hydrothermal synthesis, in a manner similar to Test Example 2-1, the obtained anatase-type TiO₂/rutile-type TiO₂ substrate were ultrasonically cleaned with pure water.

### <SEM Observation>

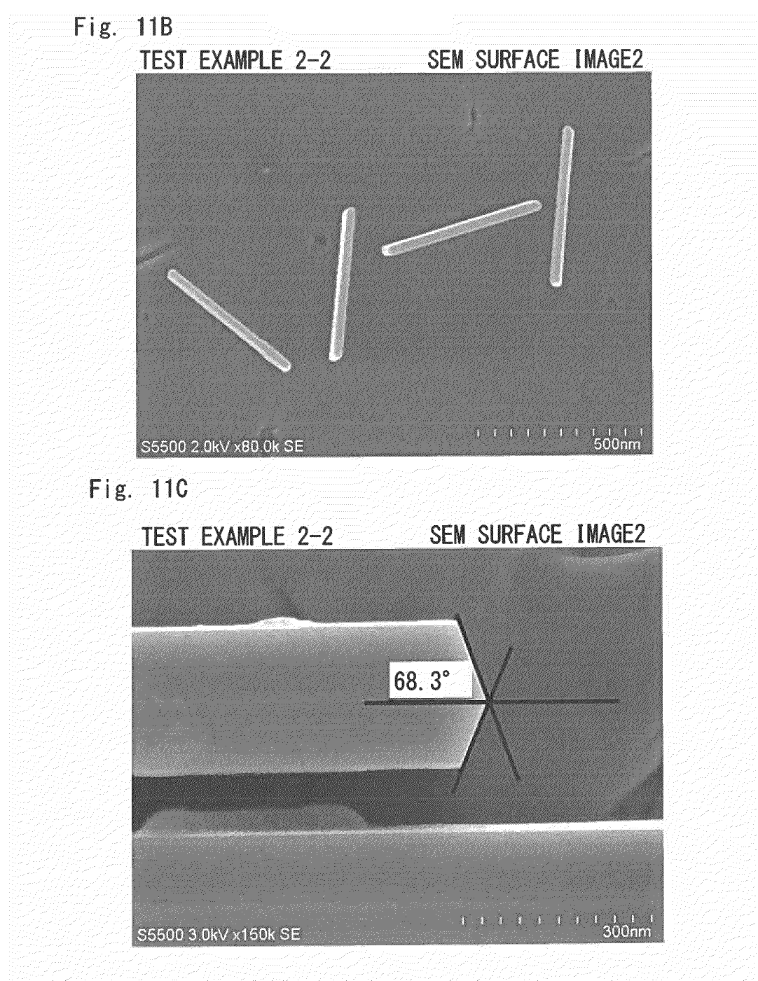

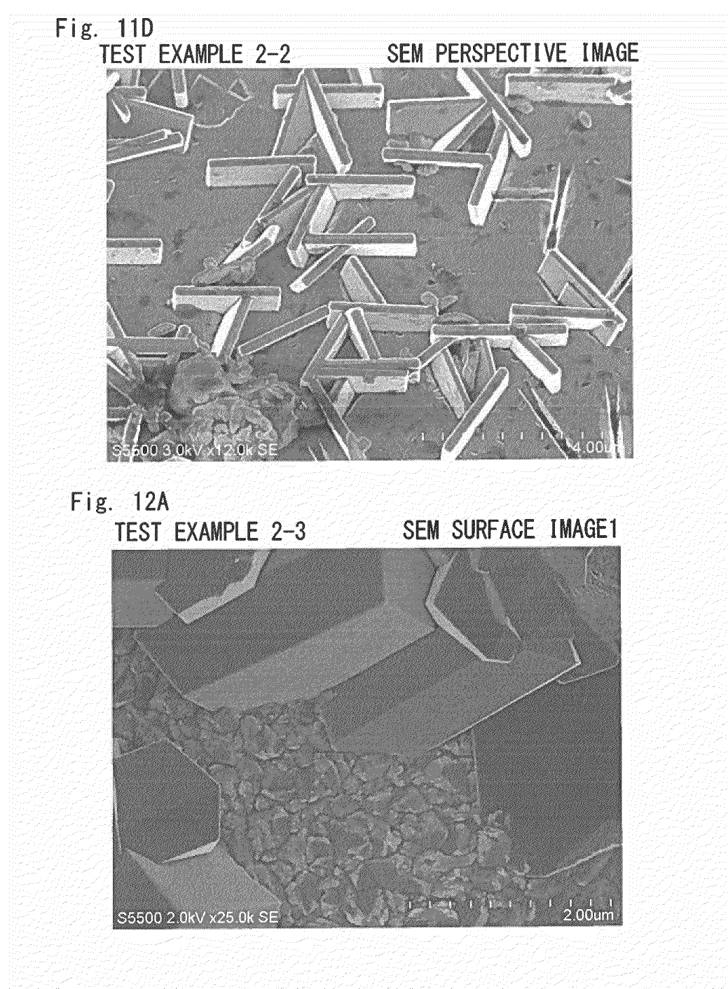

An SEM observation was performed on the anatase-type TiO₂/rutile-type TiO₂ obtained in Test Example 2-2. FIGS. 11A to 11D show SEM surface images and SEM perspective images. In a manner similar to that in Test Example 2-1, the obtained titanium oxide film consisted of plate-like crystals and had the (001) faces that were preferentially grown. In the obtained titanium oxide film, there was no fluctuation in angles of the (001) faces, which were principal surfaces of respective crystals, with respect to the deposition surface of the base material, and the membrane structure of the titanium oxide film was such that the (001) faces were almost vertical with respect to the deposition surface of the base material.

In this test example, a single-crystal substrate was used as the deposition base material. As the crystal orientation of the foundation was aligned, it was considered that the anatase-type titanium oxide crystals were uniformly grown in the [110] axis direction in which the (001) faces, which were most stable in the titanium oxide precursor solution of this test example, were preferentially grown.

The (001) face ratio was 90%.

The following Test Examples 2-3 to 2-7 used different titanium oxide precursors.

### Test Example 2-3

### Deposition Base Material

The same FTO substrate as the one in Test Example 2-1 was used as the deposition base material.

### (Deposition of Titanium Oxide Film)

0.025 ml of 37 mass % hydrochloric acid solution and 30 ml of deionized water were mixed, and the solution was stirred for five minutes. 0.075 g of TiF₄ (titanium oxide precursor) and 1.0 ml of 1-butyle-3-methylimidazolium tetrafluoroborate were added in this solution, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 90 minutes at 210° C. while being irradiated with a microwave (2.45 GHz), and a titanium oxide film having a thickness of 3 to 4 nm was deposited by the hydrothermal synthesis method. After that, the deposition base material was air-cooled to a room temperature (20 to 25° C.).

The base material which had been subjected to the hydrothermal synthesis was retrieved and ultrasonically cleaned with pure water for 30 minutes.

In this test example, TiF₄ was used as the titanium oxide precursor, and 1-butyle-3-methylimidazolium tetrafluoroborate was used as the additive agent. These contain an elemental fluorine for reducing the chemical activity of the (001) faces of the anatase-type crystals.

Although in this test example, an acidic liquid containing hydrochloric acid was used as the liquid precursor, hydrochloric acid is not an essential component and the liquid precursor can be non-acidic.

### <SEM Observation>

An SEM observation was performed on the TiO₂/FTO substrate obtained in Test Example 3.

FIGS. 12A and 12B show SEM surface images.

In a manner similar to Test Example 2-1, the obtained titanium film was a film in which the (001) faces were preferentially grown, and the (001) faces were grown in the vertical direction or the inclined direction with respect the deposition surface of the base material. However, in the obtained titanium oxide film, the level of preferential growth of the (001) faces was smaller and the level of growth of other crystal faces was greater than those in Test Examples 2-1 and 2-2.

The obtained titanium oxide film had a membrane structure in which the (001) faces were inclined by 30 to 90° with respect to the deposition surface of the base material. The (001) face ratio was 37%.

### Test Example 2-4

### Deposition Base Material

The same FTO substrate as the one in Test Example 2-1 was used as the deposition base material.

### (Deposition of Titanium Oxide Film)

0.025 ml of 37 mass % hydrochloric acid solution and 30 ml of deionized water were mixed, and the solution was stirred for five minutes. 0.075 g of TiF₄ (titanium oxide precursor) and 6.0 ml of diethylene glycol were added in this solution, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 45 minutes at 210° C. while being irradiated with a microwave (2.45 GHz), and a titanium oxide film having a thickness of 3 to 4 μm was deposited by the hydrothermal synthesis method. After that, the deposition base material was air-cooled to a room temperature (20 to 25° C.).

The base material which had been subjected to the hydrothermal synthesis was retrieved and ultrasonically cleaned with pure water for 30 minutes.

In this test example, TiF₄ was used as the titanium oxide precursor. This contains an elemental fluorine for reducing the chemical activity of the (001) faces of anatase-type crystals.

### <SEM Observation>

An SEM observation was performed on the TiO₂/FTO substrate obtained in Test Example 2-4.

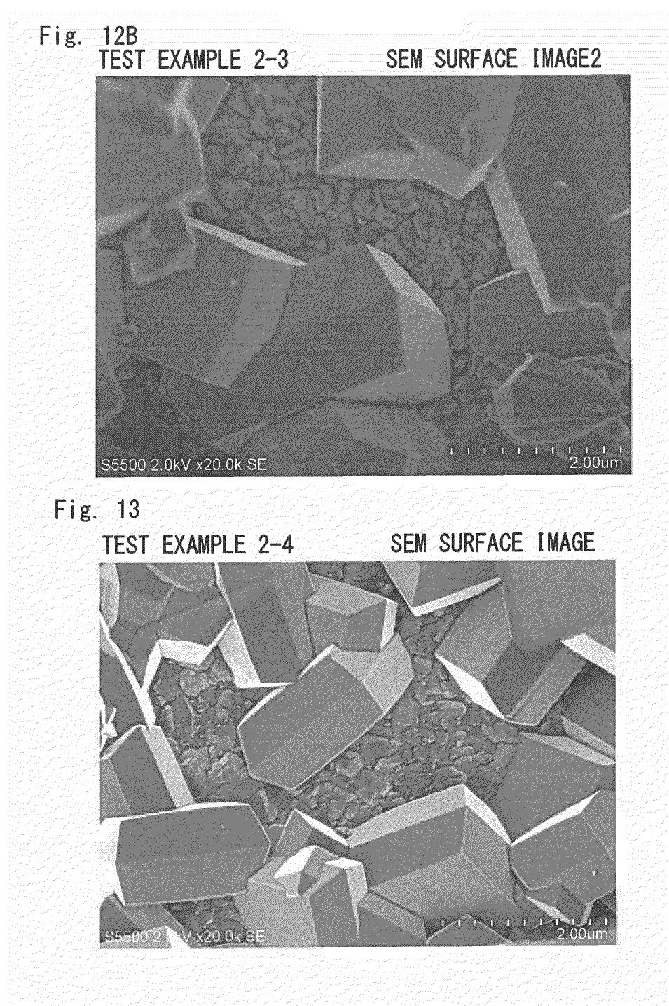

FIG. 13 shows a SEM surface image.

In a manner similar to Test Example 2-1, the obtained titanium film was a film in which the (001) faces were preferentially grown, and the (001) faces were grown in the vertical direction or the inclined direction with respect the deposition surface of the base material. However, in the obtained titanium oxide film, the level of preferential growth of the (001) faces was smaller and the level of growth of other crystal faces was greater than those in Test Examples 2-1 and 2-2.

The obtained titanium oxide film had a membrane structure in which the (001) faces were inclined by 30 to 90° with respect to the deposition surface of the base material. The (001) face ratio was 31%.

### Test Example 2-5

### Deposition Base Material

The same FTO substrate as the one in Test Example 2-1 was used as the deposition base material.

### (Deposition of Titanium Oxide Film)

15 ml of 37 mass % hydrochloric acid solution and 15 ml of deionized water were mixed, and the solution was stirred for five minutes. 0.25 g of K₂TiF₆ and 0.5 ml of Ti(OBu)₄ were added to this solution as the titanium oxide precursors, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 60 minutes at 210° C. while being irradiated with a microwave (2.45 GHz), and a titanium oxide film having a thickness of 3 to 4 nm was deposited by the hydrothermal synthesis method. After that, the deposition base material was air-cooled to a room temperature (20 to 25° C.).

The base material which had been subjected to the hydrothermal synthesis was retrieved and ultrasonically cleaned with pure water for 30 minutes.

In this test example, K₂TiF₆ was used as the titanium oxide precursor. This contains an elemental fluorine for reducing the chemical activity of the (001) faces of anatase-type crystals.

Although in this test example, an acidic liquid containing hydrochloric acid was used as the liquid precursor, hydrochloric acid is not an essential component and the liquid precursor can be non-acidic.

### <SEM Observation>

An SEM observation was performed on the TiO₂/FTO substrate obtained in Test Example 2-5.

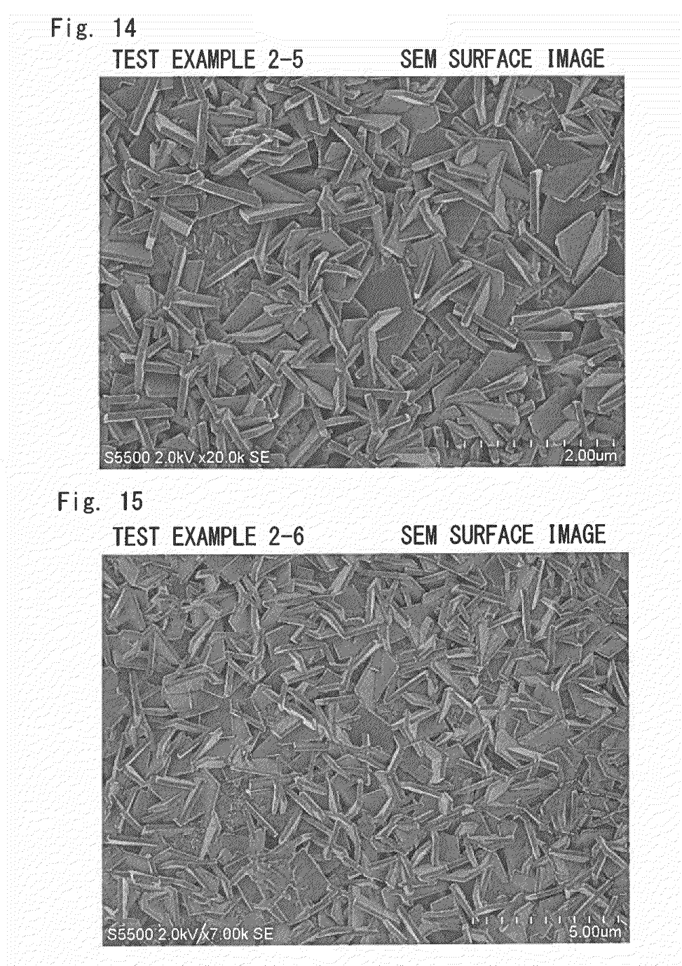

FIG. 14 shows an SEM surface image.

In a manner similar to Test Example 2-1, the obtained titanium film was a film in which the (001) faces were preferentially grown, and the (001) faces were grown in the vertical direction or the inclined direction with respect the deposition surface of the base material.

The obtained titanium oxide film had a membrane structure in which the (001) faces were inclined by 30 to 90° with respect to the deposition surface of the base material. The (001) face ratio was 81%.

### Test Example 2-6

### Deposition Base Material

The same FTO substrate as the one in Test Example 2-1 was used as the deposition base material.

### (Deposition of Titanium Oxide Film)

A titanium oxide film was obtained in a manner similar to Test Example 2-5 except that 0.48 ml of 50 mass % H₂TiF₆ aqueous solution was used in place of the 0.25 g of K₂TiF₆ and the 0.5 ml.

In this test example, H₂TiF₆ was used as the titanium oxide precursor. This contains an elemental fluorine for reducing the chemical activity of the (001) faces of anatase-type crystals.

### <SEM Observation>

An SEM observation was performed on the TiO₂/FTO substrate obtained in Test Example 2-6.

FIG. 15 shows an SEM surface image.

In a manner similar to Test Example 2-1, the obtained titanium film was a film in which the (001) faces were preferentially grown, and the (001) faces were grown in the vertical direction or the inclined direction with respect the deposition surface of the base material.

The obtained titanium oxide film had a membrane structure in which the (001) faces were inclined by 30 to 90° with respect to the deposition surface of the base material. The (001) face ratio was 86%.

### Test Example 2-7

Test Example 2-7 is an example of using a normal heater as the heating method. The same titanium oxide precursor as the one in Test Example 2-5 was used as the titanium oxide precursor.

### (Deposition Base Material)

The same FTO substrate as the one in Test Example 2-1 was used as the deposition base material.

### (Deposition of Titanium Oxide Film)

15 ml of 37 mass % hydrochloric acid solution and 15 ml of deionized water were mixed, and the solution was stirred for five minutes. 0.25 g of K₂TiF₆ and 0.5 ml of Ti(OBu)₄ were added to this solution as the titanium oxide precursors, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 15 hours at 150° C. by normal heating, and a titanium oxide film having a thickness of 3 to 4 μm was deposited by the hydrothermal synthesis method. After that, the deposition base material was air-cooled to a room temperature (20 to 25° C.).

The base material which had been subjected to the hydrothermal synthesis was retrieved and ultrasonically cleaned with pure water for 30 minutes.

### <SEM Observation>

An SEM observation was performed on the TiO₂/FTO substrate obtained in Test Example 2-7.

FIG. 16 shows an SEM surface image.

In a manner similar to Test Example 2-5, the obtained titanium film was a film in which the (001) faces were preferentially grown, and the (001) faces were grown in the vertical direction or the inclined direction with respect the deposition surface of the base material.

The obtained titanium oxide film had a membrane structure in which the (001) faces were inclined by 30 to 90° with respect to the deposition surface of the base material. The (001) face ratio was 92%.

However, this test example where the normal heater was used needed a reaction time ten or more times as long as the reaction time in Test Example 2-5 where microwave heating was performed.

### Test Example 2-8

In Test Example 2-8, a liquid precursor was produced using a non-fluorine-containing titanium oxide precursor and a fluorine-containing additive.

### (Deposition Base Material)

The same FTO substrate as the one in Test Example 2-1 was used as the deposition base material.

### (Deposition of Titanium Oxide Film)

15 ml of 37 mass % hydrochloric acid solution and 15 ml of deionized water were mixed, and the solution was stirred for five minutes. 1.0 ml of Ti(OBu)₄ (titanium oxide precursor) and 1.0 ml of 1-butyle-3-methylimidazolium tetrafluoroborate were added to this solution, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 70 minutes at 210° C. while being irradiated with a microwave (2.45 GHz), and a titanium oxide film having a thickness of 3 to 4 μm was deposited by the hydrothermal synthesis method. After that, the deposition base material was cooled to a room temperature (20 to 25° C.).

The base material which had been subjected to the hydrothermal synthesis was retrieved and ultrasonically cleaned with pure water for 30 minutes.

In this test example, 1-butyle-3-methylimidazolium tetrafluoroborate was used as the additive agent. This additive agent contains an elemental fluorine for reducing the chemical activity of the (001) faces of anatase-type crystals.

Although in this test example, an acidic liquid containing hydrochloric acid was used as the liquid precursor, hydrochloric acid is not an essential component and the liquid precursor can be non-acidic.

### <SEM Observation>

An SEM observation was performed on the TiO₂/FTO substrate obtained in Test Example 2-8.

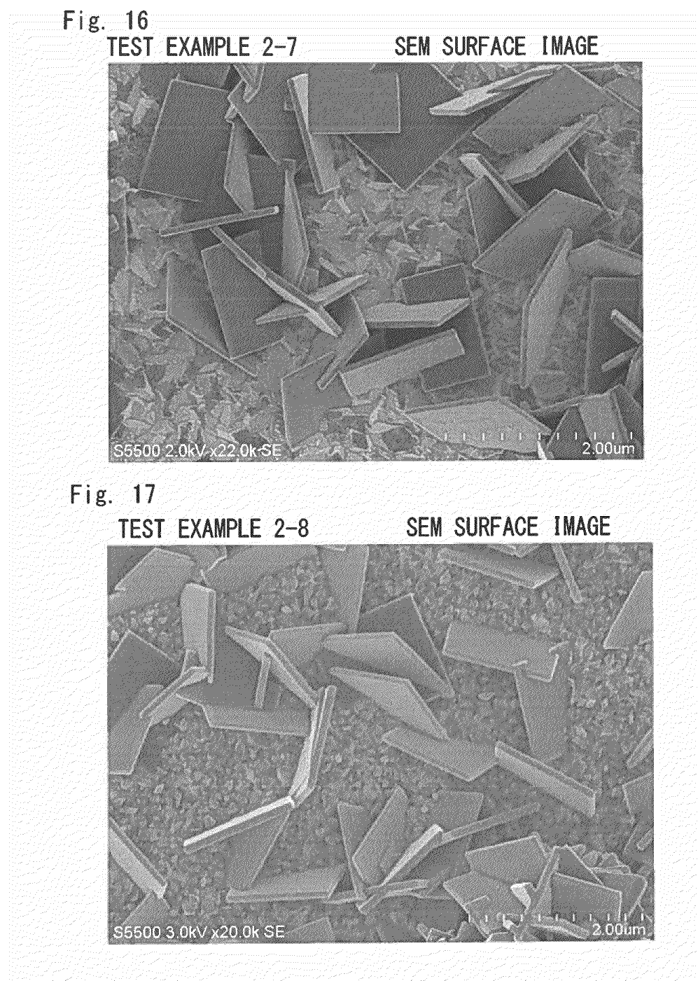

FIG. 17 shows an SEM surface image.

In a manner similar to Test Example 2-1, the obtained titanium film was a film in which the (001) faces were preferentially grown, and the (001) faces were grown in the vertical direction or the inclined direction with respect the deposition surface of the base material.

The obtained titanium oxide film had a membrane structure in which the (001) faces were inclined by 30 to 90° with respect to the deposition surface of the base material. The (001) face ratio was 86%.

A liquid precursor composition, reaction conditions, and evaluation results in Test Examples 2-1 to 2-8 are shown in Tables 1 and 2. In the tables, a BF4 salt is 1-butyle-3-methylimidazolium tetrafluoroborate (the same shall apply hereinafter).

TABLE 1

| | TEST EXAMPLE 2-1 | TEST EXAMPLE 2-2 | TEST EXAMPLE 2-3 | TEST EXAMPLE 2-4 |
|---|---|---|---|---|
| DEPOSITION SUBSTRATE | FTO SUBSTRATE | SINGLE-CRYSTAL | FTO SUBSTRATE | FTO SUBSTRATE |
| | | TiO2 SUBSTRATE | | |
| Ti PRECURSOR | (NH4)2TiF6 | (NH4)2TiF6 | TiF4 | TiF4 |
| | Ti(OBu)4 | Ti(OBu)4 | | |
| ADDITIVE AGENT | — | — | BF4 SALT | DIETHYLENE GLYCOL |
| REACTION CONDITION | MICROWAVE | MICROWAVE | MICROWAVE | MICROWAVE |
| | IRRADIATION | IRRADIATION | IRRADIATION | IRRADIATION |
| | 210° C., 75 MINS | 210° C., 75 MINS | 210° C., 90 MINS | 210° C., 45 MINS |
| INCLINED ANGLE OF (001) | 30-90 | 90 | 30-90 | 30-90 |
| FACE [°] | | | | |
| (001) FACE RATIO [%] | 83 | 90 | 37 | 31 |
| ACTUAL SURFACE AREA/ | 17 | — | — | — |
| SUBSTRATE PROJECTED AREA | | | | |

TABLE 2

| | TEST EXAMPLE 2-5 | TEST EXAMPLE 2-6 | TEST EXAMPLE 2-7 | TEST EXAMPLE 2-8 |
|---|---|---|---|---|
| DEPOSITION SUBSTRATE | FTO SUBSTRATE | FTO SUBSTRATE | FTO SUBSTRATE | FTO SUBSTRATE |
| Ti PRECURSOR | K2TiF6 | H2TiF6 | K2TiF6 | Ti(OBu)4 |
| | Ti(OBu)4 | Ti(OBu)4 | Ti(OBu)4 | |
| ADDITIVE AGENT | — | — | — | BF4 SALT |
| REACTION CONDITION | MICROWAVE | MICROWAVE | NO MICROWAVE | MICROWAVE |
| | IRRADIATION | IRRADIATION | IRRADIATION | IRRADIATION |
| | 210° C., 60 MINS | 210° C., 60 MINS | 150° C., 15 HRS | 210° C., 70 MINS |
| INCLINED ANGLE OF | 30-90 | 30-90 | 30-90 | 30-90 |
| (001) FACE [°] | | | | |
| (001) FACE RATIO [%] | 81 | 86 | 92 | 86 |

### Test Examples 3-1A to 3-1D, 3-2A, 3-2B, 3-3, and 3-4

### Deposition Base Material

The same FTO substrate as the one in Test Example 2-1 was used as the deposition base material.

### (Deposition of Titanium Oxide Film)

10 ml of 37 mass % hydrochloric acid solution and 10 ml of deionized water were mixed, and the solution was stirred for five minutes. (NH₄)₂TiF₆ and Ti(OBu)₄ were added to this solution as the titanium oxide precursors, and the solution was stirred for five minute. In the examples except Test Example 3-1A, 1-butyle-3-methylimidazolium tetrafluoroborate was further added, and the solution was stirred for five minutes. In this manner, the liquid precursor was produced. A composition of each example is shown in Tables 3 and 4. The F/Ti molar ratio is also shown in Tables 3 and 4.

In all the examples, the obtained liquid precursor was poured in a heat-resistant hermetically sealed container, and the deposition base material (FTO substrate) was immersed in the liquid precursor. The deposition base material was heated while being irradiated with a microwave (2.45 GHz), and a titanium oxide film having a thickness of 3 to 4 μm was deposited by the hydrothermal synthesis method. After that, the deposition base material was cooled to a room temperature (20 to 25° C.). Reaction conditions of each example are shown in Tables 3 and 4.

The base material which had been subjected to the hydrothermal synthesis was retrieved and ultrasonically cleaned with pure water for 30 minutes.

In these test examples, (NH₄)₂TiF₆ was used as the titanium oxide precursor and 1-butyle-3-methylimidazolium tetrafluoroborate was used as the additive agent. These contain an elemental fluorine for reducing the chemical activity of the (001) faces of anatase-type crystals.

Although in these test examples, an acidic liquid containing hydrochloric acid was used as the liquid precursor, hydrochloric acid is not an essential component and the liquid precursor can be non-acidic.

### <SEM Observation>

An SEM observation was performed on the TiO₂/FTO substrate obtained in each example.

In all examples, in a manner similar to Test Example 2-1, the obtained titanium film was a film in which the (001) faces were preferentially grown, and the (001) faces were grown in the vertical direction or the inclined direction with respect the deposition surface of the base material.

In either of the examples, the obtained titanium oxide film had a membrane structure in which the (001) faces were inclined by 30 to 90° with respect to the deposition surface of the base material.

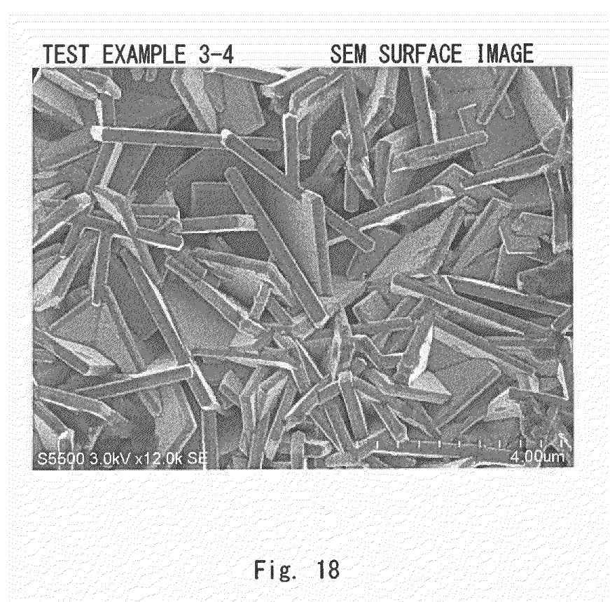

As a representative, an SEM surface image in Test Example 3-4 is shown in FIG. 18.

The (001) face ratio of the titanium oxide film obtained in each example is shown in Tables 3 and 4.

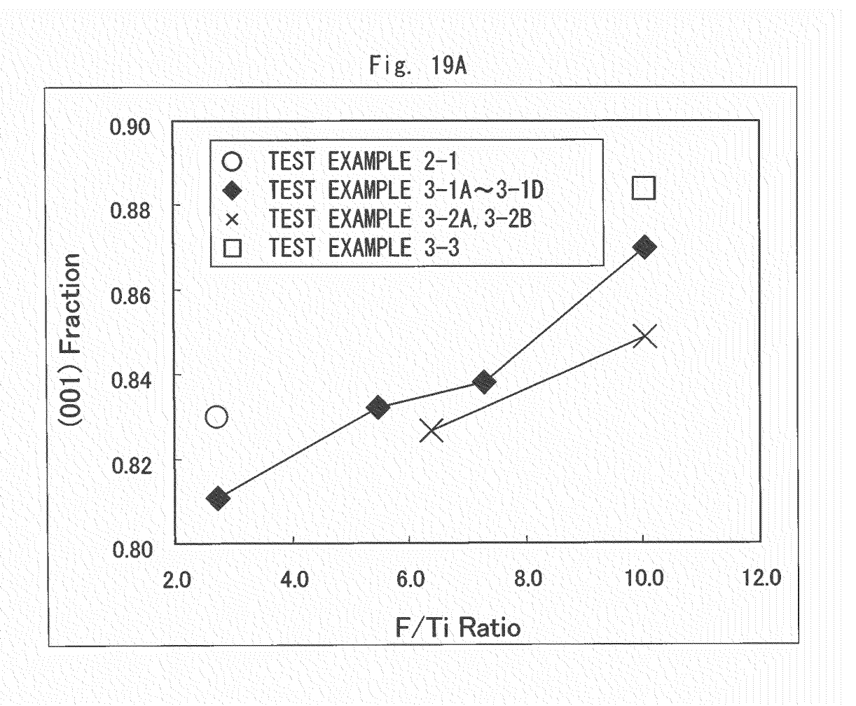

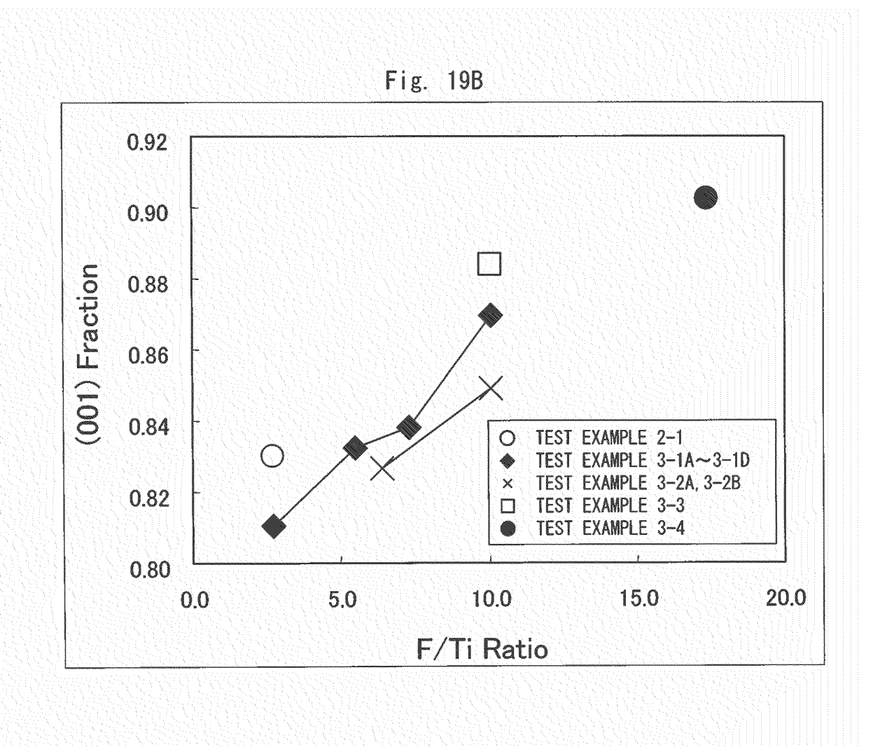

FIGS. 19A and 19B show a relationship between the F/Ti molar ratio and the (001) face ratio. The “(001) Fraction” shown as a vertical axis of the graph is the (001) face ratio.

In comparison to Test Example 3-1A in which 1-butyle-3-methylimidazolium tetrafluoroborate was not added, the level of the preferential growth of the (001) faces was greater in other test examples in which 1-butyle-3-methylimidazolium tetrafluoroborate was added. It has been revealed that the (001) face ratio improves along with an increase in the additive amount of 1-butyle-3-methylimidazolium tetrafluoroborate.

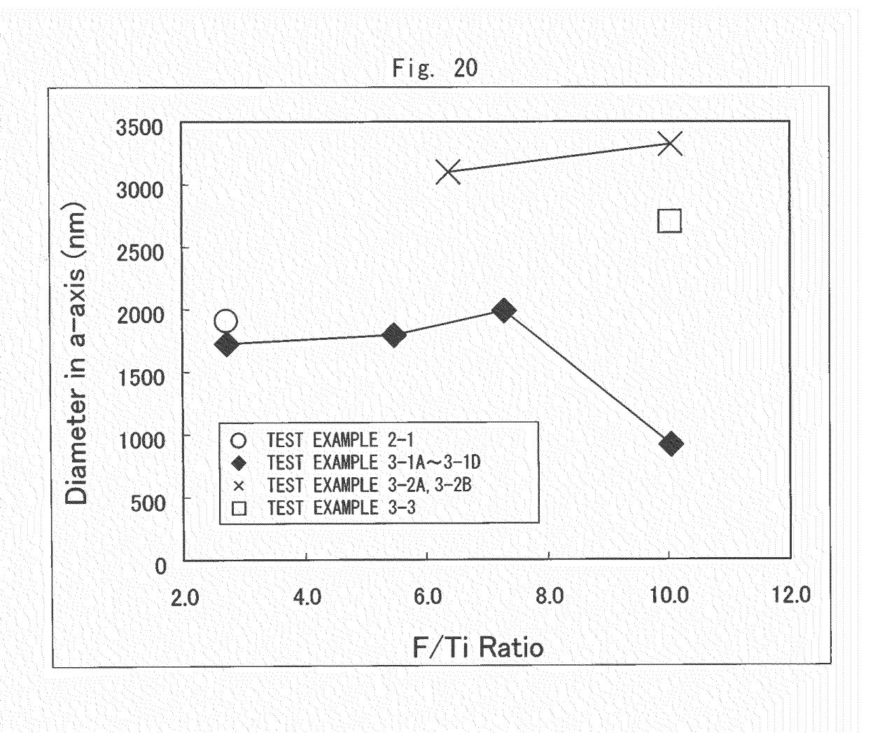

An average diameter of the top face of the plate-like crystal in the longitudinal direction captured in the SEM surface image was calculated for the titanium oxide film obtained in each example. The result is shown in Tables 3 and 4. FIG. 20 shows a relationship between the F/Ti molar ratio and the average diameter of the top face of the plate-like crystal in the longitudinal direction. The “Diameter in a-axis” shown as the vertical axis of the graph is the average diameter of the top face of the plate-like crystal in the longitudinal direction.

It has been confirmed that the plate-like crystals largely grow along with an increase in the additive amount of 1-butyle-3-methylimidazolium tetrafluoroborate.

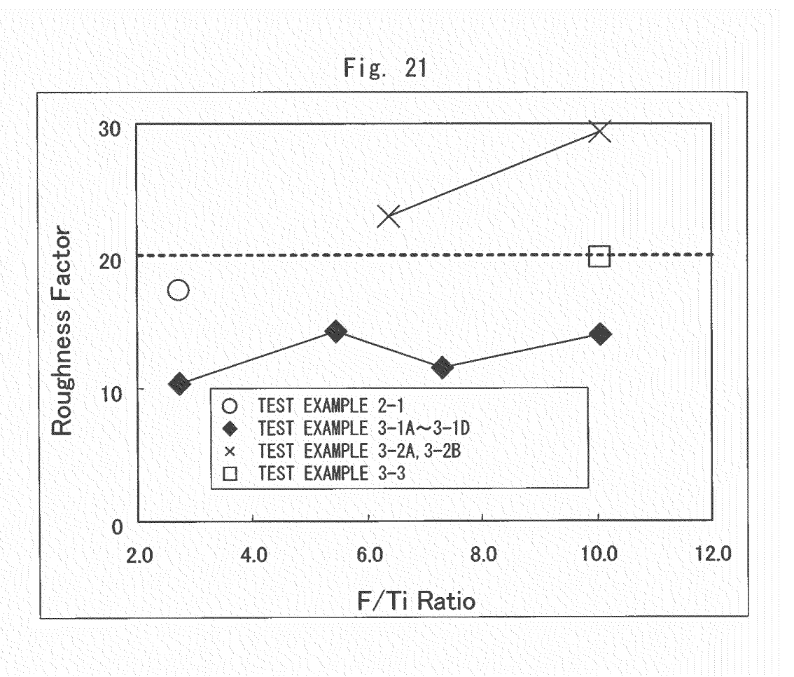

The actual surface area/substrate projected area were calculated from the SEM surface image for the titanium oxide film obtained in each example. The result is shown in Tables 3 and 4. FIG. 21 shows a relationship between the F/Ti molar ratio and the actual surface area/substrate projected area. The “Roughness Factor” shown as the vertical axis of the graph is the actual surface area/substrate projected area.

Generally in a dye-sensitized type photoelectric conversion element, the greater the actual surface area/substrate projected area, the more dyes can be supported per projected area, and thus it is known that the absorption efficiency of incident light improves, thereby improving the efficiency.

It has been confirmed that the actual surface area/substrate projected area increase along with an increase in the additive amount of 1-butyle-3-methylimidazolium tetrafluoroborate. In the test examples in which the additive amount of 1-butyle-3-methylimidazolium tetrafluoroborate was 0.2 M or greater, 20 to 40 of the actual surface area/substrate projected area were realized. Accordingly, it has been revealed that the additive amount of 1-butyle-3-methylimidazolium tetrafluoroborate is preferably 0.2 M or greater, for example, in the range of 0.2 to 0.4 M.

TABLE 3

| | TEST | TEST | | |
|---|---|---|---|---|
| | EXAMPLE 3-1A | EXAMPLE 3-1B | TEST EXAMPLE 3-1C | TEST EXAMPLE 3-1D |
| DEPOSITION SUBSTRATE | FTO SUBSTRATE | FTO SUBSTRATE | FTO SUBSTRATE | FTO SUBSTRATE |
| (NH4)2TiF6 [M] | 0.052 | 0.051 | 0.051 | 0.05 |
| Ti(OBu)4 [M] | 0.062 | 0.062 | 0.061 | 0.06 |
| BF4 SALT [M] | 0 | 0.078 | 0.128 | 0.202 |
| F/Ti MOLAR RATIO | 2.7 | 5.5 | 7.3 | 10.1 |
| REACTION CONDITION | MICROWAVE | MICROWAVE | MICROWAVE | MICROWAVE |
| | IRRADIATION | IRRADIATION | IRRADIATION | IRRADIATION |
| | 210° C., 60 MINS | 210° C., 60 MINS | 210° C., 60 MINS | 210° C., 60 MINS |
| INCLINED ANGLE OF (001) | 30-90 | 30-90 | 30-90 | 30-90 |
| FACE [°] | | | | |
| (001) FACE RATIO [%] | 81 | 83 | 84 | 87 |
| AVERAGE DIAMETER OF TOP | 1724 | 1790 | 1993 | 915 |
| FACE OF PLATE-LIKE CRYSTAL | | | | |
| IN LONGITUDINAL | | | | |
| DIRECTION | | | | |
| ACTUAL SURFACE AREA/ | 10 | 14 | 12 | 14 |
| SUBSTRATE PROJECTED AREA | | | | |

TABLE 4

| | TEST EXAMPLE 3-2A | TEST EXAMPLE 3-2B | TEST EXAMPLE 3-3 | TEST EXAMPLE 3-4 |
|---|---|---|---|---|
| DEPOSITION SUBSTRATE | FTO SUBSTRATE | FTO SUBSTRATE | FTO SUBSTRATE | FTO SUBSTRATE |
| (NH4)2TiF6 [M] | 0.05 | 0.098 | 0.095 | 0.048 |
| Ti(OBu)4 [M] | 0.12 | 0.11 | 0.11 | 0.058 |
| BF4 SALT [M] | 0.2 | 0.38 | 0.38 | 0.39 |
| F/Ti MOLAR RATIO | 6.4 | 10.1 | 10.1 | 17.4 |
| REACTION CONDITION | MICROWAVE | MICROWAVE | MICROWAVE | MICROWAVE |
| | IRRADIATION | IRRADIATION | IRRADIATION | IRRADIATION |
| | 210° C., 60 MINS | 210° C., 60 MINS | 180° C., 180 MINS | 210° C., 240 MINS |
| INCLINED ANGLE OF (001) | 30-90 | 30-90 | 30-90 | 30-90 |
| FACE [°] | | | | |
| (001) FACE RATIO [%] | 83 | 85 | 88 | 90 |
| AVERAGE DIAMETER OF TOP | 3100 | 3300 | 2700 | 2700 |
| FACE OF PLATE-LIKE CRYSTAL | | | | |
| IN LONGITUDINAL DIRECTION | | | | |
| ACTUAL SURFACE AREA/ | 23 | 29 | 20 | 7 |
| SUBSTRATE PROJECTED AREA | | | | |

### Test Example 4-1

### Deposition Base Material

The same FTO substrate as the one in Test Example 1-1 was used as the deposition base material.

### (Deposition of Titanium Oxide Fine Particle Film)

The process of coating a sol (Ti sol manufactured by Solaronix) containing a titanium oxide precursor on the deposition base material (FTO substrate) and drying the deposition base material for six minutes on a hot plate at 130° C. was repeated twice. Further, a sol (Ti-nanoxide 300 manufactured by Solarnix) containing titanium oxide as scattered particles was coated, the deposition base material was calcined for 30 minutes at 450° C., and a titanium oxide fine particle film having an average particle diameter of 10 nm and a thickness of 10 to 15 μm was formed.

In a manner similar to Test Example 2-1, a dye-sensitized type photoelectric conversion element was obtained except that this deposition base material was used as the negative electrode substrate.

### Test Example 4-2

### Deposition Base Material

The same FTO substrate as the one in Test Example 4-1 was used as the deposition base material.

### (Deposition of Titanium Oxide Film)

15 ml of 37 mass % hydrochloric acid solution and 15 ml of deionized water were mixed, and the solution was stirred for five minutes. 0.32 g of (NH₄)₂TiF₆ and 0.6 ml of Ti(OBu)₄ were added to this solution as the titanium oxide precursors, the solution was stirred for five minutes, and a liquid precursor was produced.

The above-mentioned liquid precursor was poured in a heat-resistant hermetically sealed container, and the deposition base material (FTO substrate) was immersed in the liquid precursor. The deposition base material was heated for 75 minutes at 210° C. while being irradiated with a microwave (2.45 GHz), and a first titanium oxide film consisting of anatase-type plate-like crystals having a thickness of 3 to 4 nm was deposited by the hydrothermal synthesis method. After that, the deposition base material was cooled to a room temperature (20 to 25° C.).

The base material which had been subjected to the hydrothermal synthesis was retrieved and ultrasonically cleaned with pure water for 30 minutes.

The obtained TiO₂/FTO substrate was calcined in an air atmosphere in an electric furnace, and water which is a solvent, impurities, and an elemental fluorine were removed. The calcination profile was; five minutes at 325° C.→five minutes at 375° C.→15 minutes at 450° C.→15 minutes at 500° C.

In this test example, two kinds of precursors, which are (NH₄)₂TiF₆ and Ti(OBu)₄ were used as the titanium oxide precursor(s). Between these precursors, the former one contains an elemental fluorine for reducing the chemical activity of the (001) faces of the anatase-type crystals.

Although in this test example, an acidic liquid containing hydrochloric acid was used as the liquid precursor, hydrochloric acid is not an essential component and the liquid precursor can be non-acidic.

A sol (Ti sol manufactured by Solaronix) containing a titanium oxide precursor was coated on the first titanium oxide film, the deposition substrate was dried for 20 minutes at 80° C. using a hot plate, and dried for six minutes at 130° C. These processes were repeated twice, a sol (Ti-nanoxide 300 manufactured by Solaronix) containing titanium oxide particles as scattered particles was coated, and the substrate was calcined for 30 minutes at 450° C., so that a second titanium oxide film, which is a titanium oxide fine particle film having an average particle diameter of 10 nm, was deposited.

In this manner, a titanium oxide laminated film was obtained. The obtained laminated film had a membrane structure in which a plurality of titanium oxide fine particles entered into gaps of the first titanium oxide film, and the plurality of titanium oxide fine particles having a thickness of 10 to 15 μm were deposited on the first titanium oxide film.

### (Manufacturing Dye-Sensitized Type Photoelectric Conversion Element)

The obtained TiO₂ laminated film/FTO substrate were immersed in a dye-sensitized agent solution which a dye-sensitized agent N719 manufactured by Solarnix was dissolved in a mixed solution of ethanol/t-butanol (capacity ratio 1/1) for twelve hours, and a negative electrode substrate was obtained. A chemical expression of the dye-sensitized agent that was used is shown in [Chemical Expression 2]. This dye-sensitized agent has wide absorption in the visible region of 300 to 750 nm. This dye-sensitized agent recorded the best efficiency so far and is known as one of the most efficient dyes.

A dye-sensitized type photoelectric conversion element was obtained in a manner similar to Test Example 2-1 except that the above-mentioned negative electrode substrate for supporting the dye-sensitized agent was used.

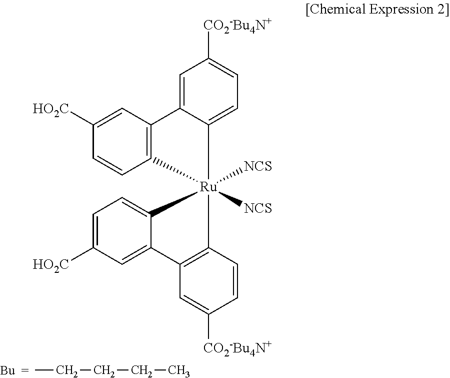

### <SEM Observation>

An SEM observation was performed on the first titanium oxide film/FTO substrate and the second titanium oxide film/first titanium oxide film/FTO substrate that were obtained in Test Example 4-2.

Before the second titanium oxide film was deposited, the first titanium oxide film had a membrane structure in which the (001) faces were grown in the vertical direction or the inclined direction with respect the deposition surface of the base material, in a manner similar to the titanium oxide film in Test Example 2-1. Further, the angle of the (001) face to the deposition surface of the base material was 30 to 90°, and the (001) face ratio was about 80%.

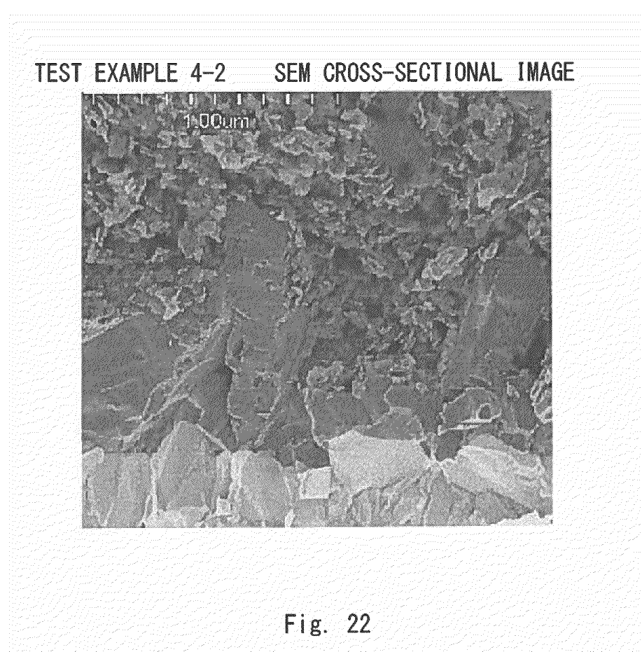

FIG. 22 shows an SEM cross-sectional image of the second titanium oxide film/the first titanium oxide film/FTO substrate.

Even when the second titanium oxide film was laminated, there was no change in the membrane structure of the first titanium oxide film.

### <Measuring N719 Dye-Supporting Amount>

In a manner similar to Test Examples 1-1 and 2-1, dye-supporting amounts were calculated for the titanium oxide fine particle film in Test Example 4-1 and the titanium oxide laminated film in Test Example 4-2. In Test Example 4-2, the thickness of the second titanium oxide film is ten or more times as thick as the first titanium oxide film. Therefore, the dye-supporting amounts of the titanium oxide fine particle film in Test Example 4-1 and the titanium oxide laminated film in Test Example 4-2 were substantially equivalent levels.

### <Evaluation of Photoelectric Conversion Property>

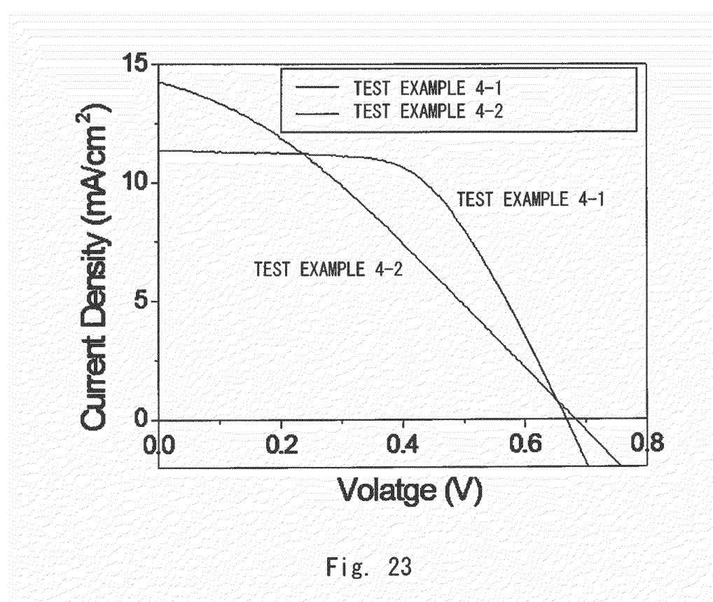

A measurement of photocurrent-voltage property at a room temperature was performed on the photoelectric conversion elements in Test Examples 4-1 and 4-2 that used the dye-sensitized agent N719 using pseudo sunlight (AM1.5, crystalline silicon standard, manufactured by Yamashita Denso Corporation). The result is shown in FIG. 23.

Maximum photocurrent Jsc, optical maximum voltage Voc, Fill Factor FF, and maximum conversion efficiency Eff are as shown in Table 5.

In Test Example 4-2, a high photoelectric conversion response was confirmed in both of the photocurrent and the optical voltage in comparison to Test Example 4-1.

In Test Example 4-2, the Fill Factor FF and the maximum conversion efficiency Eff were lower than those in Test Example 4-1. It is known that the composition of an electrolyte largely influences the Fill Factor FF. It is considered that an electrolyte composition that was optimized for Test Example 4-1, which is a related art, was not an optimum composition for Test 4-2.

However, in Test Example 4-2, high photocurrent was obtained under a low voltage applied condition, and a high optical voltage was obtained under a low current condition. The result of Test Example 4-2 remarkably exceeds those of Text Example 4-1 both under the low loading condition and high loading condition.

This indicates a possibility that can achieve a property that remarkably exceeds actual device usage conditions.

In Test Example 4-2, it can be considered that when the anatase-type plate-like single crystals having a high electron transfer property were inserted in a porous structure, the electron diffusion in the fine particles and the membrane resistance improved, thereby improving the electron collection efficiency, and thus high photocurrent was obtained. It can be further considered that in the titanium oxide electrode consisting of anatase-type plate-like crystals having many of the (001) faces, the titanium oxide conduction band was positioned closer to the negative side, and an open circuit voltage improved because of the high conduction band potential.

TABLE 5

| | TEST | |
|---|---|---|
| | EXAMPLE 4-1 | TEST EXAMPLE 4-2 |
| Jsc [mA/cm2] | 11.4 | 14.2 |
| Voc [V] | 0.67 | 0.68 |
| FF | 0.57 | 0.32 |
| Eff [%] | 4.37 | 3.04 |

The present application claims priority rights of and is based on Japanese Patent Application No. 2011-282584 filed on Dec. 26, 2011 in the Japanese Patent Office, the entire contents of which are hereby incorporated by reference.

### INDUSTRIAL APPLICABILITY

The titanium oxide laminated film and the titanium oxide film of the present invention can be preferably used as a semiconductor film and the like for supporting a dye-sensitized agent in a dye-sensitized type photoelectric conversion element.

### REFERENCE SIGNS LIST

1 TITANIUM OXIDE LAMINATED FILM
2 BASE MATERIAL
11a DEPOSITION SURFACE OF BASE MATERIAL
12 FIRST TITANIUM OXIDE FILM
12a (001) FACE OF ANATASE-TYPE CRYSTAL
13 SECOND TITANIUM OXIDE FILM
13a TITANIUM OXIDE FINE PARTICLE
100 DYE-SENSITIZED TYPE PHOTOELECTRIC CONVERSION ELEMENT
110 NEGATIVE ELECTRODE SUBSTRATE
111 SUBSTRATE
112 FIRST CONDUCTIVE FILM
113 SEMICONDUCTOR FILM
120 POSITIVE ELECTRODE SUBSTRATE
121 SUBSTRATE
122 SECOND CONDUCTIVE FILM
123 CATALYST LAYER
130 ELECTROLYTE LAYER
140 SEAL MATERIAL

1. A titanium oxide laminated film comprising:
a first titanium oxide film that consists of a plurality of anatase-type plate-like crystals, (001) faces of the anatase-type plate-like crystals being grown in a vertical direction or an inclined direction with respect to a deposition surface of a base material; and
a second titanium oxide film that has a specific area greater than a specific surface area of the first titanium oxide film and consists of a plurality of titanium oxide fine particles,
wherein the first titanium oxide film and the second titanium oxide film are sequentially laminated on the base material.

2. The titanium oxide laminated film according to claim 1, wherein an inclined angle of the anatase (001) faces of the first titanium oxide film with respect to the deposition surface is 10° or greater.

3. The titanium oxide laminated film according to claim 2, wherein the inclined angle of the anatase (001) faces of the first titanium oxide film with respect to the deposition surface is 30° or greater.

4. The titanium oxide laminated film according to claim 1, wherein in the first titanium oxide film, a ratio of areas of the (001) faces to a total area of all crystal faces of the anatase-type crystals is 10% or greater.

5. The titanium oxide laminated film according to claim 4, wherein in the first titanium oxide film, the ratio of the areas of the (001) faces to the total area of all crystal faces of the anatase-type crystals is 50% or greater.

6. The titanium oxide laminated film according to claim 5, wherein in the first titanium oxide film, the ratio of the areas of the (001) faces to the total area of all crystal faces of the anatase-type crystals is 80% or greater.

7. The titanium oxide laminated film according to claim 1, wherein in the first titanium oxide film, an actual surface area/substrate projected area is 20 or greater.

8. A titanium oxide film formed on a base material and consisting of a plurality of anatase-type plate-like crystals having (001) faces grown in a vertical direction or an inclined direction with respect to a deposition surface of the base material, wherein
an inclined angle of the anatase (001) faces with respect to the deposition surface is 10° or greater,
a ratio of areas of the (001) faces to a total area of all crystal faces of the anatase-type crystals is 10% or greater, and
an actual surface area/substrate projected area is 20 or greater.

9. A titanium oxide liquid precursor that is used for depositing a titanium oxide film consisting of a plurality of anatase-type plate-like crystals having (001) faces grown in a vertical direction or an inclined direction with respect to a deposition surface of a base material, the titanium oxide liquid precursor comprising:
a titanium oxide precursor; and
a non-acidic additive agent consisting of a salt of [BF₄]⁻ and/or a salt of [PF₆]⁻.

10. A titanium oxide liquid precursor that is used for depositing a titanium oxide film consisting of a plurality of anatase-type plate-like crystals having (001) faces grown in a vertical direction or an inclined direction with respect to a deposition surface of a base material, the titanium oxide liquid precursor comprising:
a titanium oxide precursor; and
a non-acidic additive agent consisting of an alcohol and/or an amine.

11. The titanium oxide liquid precursor according to claim 9, wherein the titanium oxide precursor contains TiF₄ and/or a salt of [TiF₆]²⁻.

12. A method of manufacturing a titanium oxide film consisting of a plurality of anatase-type plate-like crystals in which (001) faces are grown in a vertical direction or an inclined direction with respect to a deposition surface of a substrate, the method comprising:
depositing the titanium oxide film by a liquid-phase process using the titanium oxide liquid precursor according to claim 9.

13. The method according to claim 12, wherein crystals are grown while being irradiated with a microwave.

14. A dye-sensitized agent type photoelectric conversion element comprising:
a base material; and
a semiconductor film that supports a dye-sensitized agent,
wherein the semiconductor film contains the titanium oxide laminated film according to claim 1.

15. (canceled)

16. The dye-sensitized agent type photoelectric conversion element according to claim 14, wherein
a dye-sensitized agent that indicates absorption in a wavelength region of 700 to 900 nm is used as the dye-sensitized agent, and
the dye-sensitized agent type photoelectric conversion element indicates a photoelectric conversion response in the wavelength region of 700 to 900 nm.

17. A dye-sensitized agent type photoelectric conversion element comprising:
a base material; and
a semiconductor film that supports a dye-sensitized agent, wherein
the semiconductor film includes a titanium oxide film consisting of a plurality of anatase-type plate-like crystals, the anatase-type plate-like crystals having (001) faces grown in a vertical direction or an inclined direction with respect to a deposition surface of the substrate,
a dye-sensitized agent that indicates absorption in a wavelength region of 700 to 900 nm is used as the dye-sensitized agent, and
the dye-sensitized agent type photoelectric conversion element indicates a photoelectric conversion response in the wavelength region of 700 to 900 nm.

18. A dye-sensitized agent type photoelectric conversion element comprising:
a base material; and
a semiconductor film that supports a dye-sensitized agent,
wherein the semiconductor film contains the titanium oxide film according to claim 8.
